(19) United States
(12) Patent Application Publication
(10) Pub. No.: US 2012/0249250 A1
(43) Pub. Date: Oct. 4, 2012

(54) Quadrature Voltage Controlled Oscillator

(75) Inventors: Kuang-Wei Cheng, Singapore (SG); Minkyu Je, Singapore (SG)

(73) Assignee: Agency for Science, Technology and Research

(21) Appl. No.: 13/433,776

(22) Filed: Mar. 29, 2012

(30) Foreign Application Priority Data
Mar. 31, 2011 (SG) 201102304-1

(51) Int. Cl. H03B 27/00

(52) U.S. Cl. 331/45

(57) ABSTRACT

According to embodiments of the present invention, a quadrature voltage controlled oscillator is provided. The quadrature voltage controlled oscillator includes a first voltage controlled oscillator and a second voltage controlled oscillator respectively comprising an inductor having a first terminal and a second terminal, a first capacitor, a second capacitor, a third capacitor and a fourth capacitor respectively comprising a first terminal and a second terminal, a first transistor, a second transistor, a third transistor and a fourth transistor respectively comprising a source terminal, a drain terminal and a gate terminal, wherein the first terminal of the inductor is coupled to the first terminal of the first capacitor, and the second terminal of the inductor is coupled to the second terminal of the first capacitor, wherein the drain terminal of the first transistor is coupled to the first terminal of the inductor, the first terminal of the first capacitor, the first terminal of the second capacitor, and the gate terminal of the fourth transistor, wherein the drain terminal of the second transistor is coupled to the second terminal of the inductor, the second terminal of the first capacitor, the first terminal of the third capacitor, and the gate terminal of the third transistor, wherein the source terminal of the first transistor is coupled to the second terminal of the second capacitor, the drain terminal of the third transistor, and the first terminal of the fourth capacitor, wherein the source terminal of the second transistor is coupled to the second terminal of the third capacitor, the drain terminal of the fourth transistor, and the second terminal of the fourth capacitor, wherein the gate terminal of the first transistor of the first voltage controlled oscillator is directly coupled to the first terminal of the inductor of the second voltage controlled oscillator, wherein the gate terminal of the second transistor of the first voltage controlled oscillator is directly coupled to the second terminal of the inductor of the second voltage controlled oscillator, wherein the gate terminal of the first transistor of the second voltage controlled oscillator is directly coupled to the second terminal of the inductor of the first voltage controlled oscillator, wherein the gate terminal of the second transistor of the second voltage controlled oscillator is directly coupled to the first terminal of the inductor of the first voltage controlled oscillator.

This application claims the benefit of priority of Singapore patent application No. 201102304-1, filed 31 Mar. 2011, the content of it being hereby incorporated by reference in its entirety for all purposes.

### FIELD OF THE INVENTIONS

Various embodiments relate to a quadrature voltage controlled oscillator (QVCO).

### BACKGROUND OF THE INVENTIONS

A quadrature receiver front-end is an essential component for integrated communication systems. It contains two mixers in an in-phase receiving path and in a quadrature receiving path, respectively, converting the received signal into a low intermediate frequency (IF). In each receiving path, the mixers are delivered by an in-phase signal and a quadrature signal, respectively. A key building block for such I/Q modulation (demodulation) is the voltage-controlled oscillator (VCO) with quadrature outputs, e.g. the quadrature VCO (QVCO). However, the mismatch of the amplitude and phase between the in-phase and the quadrature signals degrade the image rejection and affect the system performance. Hence, it is necessary to keep the in-phase and quadrature branches symmetrical.

There are many options available to generate quadrature signals. Firstly, a polyphase filter is exceptionally good at providing quadrature output from VCO but requires additional VCO output buffers for signal attenuation in the passive RC filter. In addition, the quadrature phase accuracy is dependent on device matching and the limited operating frequency range restricts its application in implementation. A second option is to operate the VCO at double frequency, followed by two frequency dividers. However, as the VCO operates at higher frequency, it suffers from increasing power consumption and sensitivity to the duty cycle of the VCO waveform. A third approach to generate quadrature signals is through the use of a quadrature VCO (QVCO) which couples two identical oscillators operating with a 90° phase shift between each other. QVCO can achieve better quadrature phase accuracy and lower power consumption compared to the first two options above. However, its primary drawback is doubled die area and power consumption compared to a single VCO. In addition, the coupled topology between the two oscillators greatly affects the phase noise, and quadrature phase accuracy, and the coupling devices or oscillators may induce too much excess phase noise.

For example, conventional QVCOs such as parallel-coupled QVCOs (P-QVCOs) require high power and a trade-off between quadrature phase accuracy and phase noise, while top-series QVCOs (TS-QVCOs), bottom-series QVCOs (BS-QVCOs) and gate-modulated QVCOs (GM-QVCOs) have a smaller coupling efficiency and require additional coupling devices.

### SUMMARY

According to an embodiment, a quadrature voltage controlled oscillator is provided. The quadrature voltage controlled oscillator may include a first voltage controlled oscillator and a second voltage controlled oscillator respectively including an inductor having a first terminal and a second terminal, a first capacitor, a second capacitor, a third capacitor and a fourth capacitor respectively including a first terminal and a second terminal, a first transistor, a second transistor, a third transistor and a fourth transistor respectively including a source terminal, a drain terminal and a gate terminal, wherein the first terminal of the inductor is coupled to the first terminal of the first capacitor, and the second terminal of the inductor is coupled to the second terminal of the first capacitor, wherein the drain terminal of the first transistor is coupled to the first terminal of the inductor, the first terminal of the first capacitor, the first terminal of the second capacitor, and the gate terminal of the fourth transistor, wherein the drain terminal of the second transistor is coupled to the second terminal of the inductor, the second terminal of the first capacitor, the first terminal of the third capacitor, and the gate terminal of the third transistor, wherein the source terminal of the first transistor is coupled to the second terminal of the second capacitor, the drain terminal of the third transistor, and the first terminal of the fourth capacitor, wherein the source terminal of the second transistor is coupled to the second terminal of the third capacitor, the drain terminal of the fourth transistor, and the second terminal of the fourth capacitor, wherein the gate terminal of the first transistor of the first voltage controlled oscillator is directly coupled to the first terminal of the inductor of the second voltage controlled oscillator, wherein the gate terminal of the second transistor of the first voltage controlled oscillator is directly coupled to the second terminal of the inductor of the second voltage controlled oscillator, wherein the gate terminal of the first transistor of the second voltage controlled oscillator is directly coupled to the second terminal of the inductor of the first voltage controlled oscillator, wherein the gate terminal of the second transistor of the second voltage controlled oscillator is directly coupled to the first terminal of the inductor of the first voltage controlled oscillator.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIGS. 1A and 1B show schematics of an LC cross-coupled voltage controlled oscillator (VCO) and a Colpitts voltage controlled oscillator (VCO) respectively of the prior art.

FIG. 2A shows a schematic of a differential Colpitts oscillator.

FIG. 2B shows a schematic of a differential Colpitts oscillator, according to various embodiments.

FIG. 2C shows a plot of the simulated effective impulse sensitivity functions of the differential Colpitts oscillators of the embodiments of FIGS. 2A and 2B.

FIG. 3A shows a schematic block diagram of a quadrature voltage controlled oscillator, according to various embodiments.

FIG. 3B shows a schematic block diagram of a quadrature voltage controlled oscillator, according to various embodiments.

FIGS. 4A and 4B show a schematic of a Colpitts quadrature voltage controlled oscillator (QVCO), according to various embodiments.

FIGS. 5A and 5B show a schematic of a Colpitts quadrature voltage controlled oscillator (QVCO), according to various embodiments.

FIG. 6 shows a plot of waveforms from a Colpitts quadrature voltage controlled oscillator (QVCO) of various embodiments.

FIG. 7 shows a plot of tuning range (TR) of a Colpitts quadrature voltage controlled oscillator (QVCO) of various embodiments.

FIG. 8 shows a plot of phase noise of a Colpitts quadrature voltage controlled oscillator (QVCO) of various embodiments.

FIG. 9 shows a plot of simulated phase noises of Colpitts quadrature voltage controlled oscillators (QVCOs) of various embodiments and a conventional quadrature voltage controlled oscillator.

### DETAILED DESCRIPTION OF THE INVENTIONS

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Embodiments described in the context of one of the devices are analogously valid for the other device.

In the context of various embodiments, the phrase “at least substantially” may include “exactly” and a variance of +/−5% thereof. As an example and not limitations, “A is at least substantially same as B” may encompass embodiments where A is exactly the same as B, or where A may be within a variance of +/−5%, for example of a value, of B, or vice versa.

In the context of various embodiments, the term “about” or “approximately” as applied to a numeric value encompasses the exact value and a variance of +/−5% of the value.

As used herein, the term “and/or” includes any and all combinations of one or more of the associated listed items.

Various embodiments relate to circuits for quadrature signals generation, for example for communication systems. As an example, quadrature signals may be generated in a quadrature receiver.

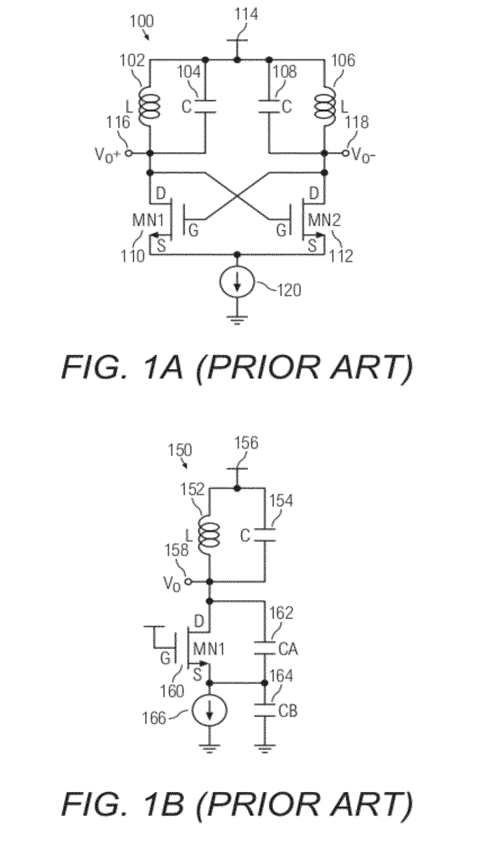

FIG. 1A shows a schematic of an LC cross-coupled voltage controlled oscillator (VCO) 100 of the prior art. The LC cross-coupled VCO 100 includes a pair of LC circuits or LC tanks with an inductor 102 in parallel with a capacitor 104 and another inductor 106 in parallel with another capacitor 108, and a pair of transistors 110, 112.

A respective first terminal of the inductor 102 and the capacitor 104 are coupled to each other and to an input terminal 114 and a respective second terminal of the inductor 102 and the capacitor 104 are coupled to each other and to a first output terminal (Vo+) 116. A respective first terminal of the inductor 106 and the capacitor 108 are coupled to each other and to an input terminal 114 and a respective second terminal of the inductor 106 and the capacitor 108 are coupled to each other and to a second output terminal (Vo−) 118.

In addition, the respective second terminal of each of the inductor 102 and the capacitor 104 are coupled to a drain (D) terminal of the transistor (MN1) 110, which is also cross coupled to a gate (G) terminal of the transistor (MN2) 112, while the respective second terminal of each of the inductor 106 and the capacitor 108 are coupled to a drain (D) terminal of the transistor (MN2) 112, which is also cross coupled to a gate (G) terminal of the transistor (MN1) 110.

The respective source (S) terminal of each of the transistors (MN1, MN2) 110, 112 are coupled to each other and to a first terminal of a current source 120, where a second terminal of the current source 120 is coupled to ground (i.e. grounded).

The LC tank VCO 100 with the cross-coupled pair of transistors 110, 112 has attracted many interests due to its easy implantation, reliable start-up, and good phase noise. However, the thermal and flicker noise perturb the oscillator outputs at their zero-crossings, thus degrading the VCO phase noise.

FIG. 1B shows a schematic of a Colpitts voltage controlled oscillator (VCO) 150 of the prior art. The Colpitts VCO 150 includes an LC circuit or LC tank with an inductor 152 in parallel with a capacitor 154.

A respective first terminal of the inductor 152 and the capacitor 154 are coupled to each other and to an input terminal 156, while a respective second terminal of the inductor 152 and the capacitor 154 are coupled to each other and to an output terminal (Vo) 158. In addition, the respective second terminal of each of the inductor 152 and the capacitor 154 are coupled to a drain (D) terminal of a transistor (MN1) 160 and a first terminal of a capacitor (CA) 162. A second terminal of the capacitor (CA) 162 is coupled to a first terminal of another capacitor (CB) 164 and the second terminal of the capacitor (CB) 164 is coupled to ground. The capacitor (CA) 162 and the capacitor (CB) 164 may form a capacitive divider.

In addition, a source (S) terminal of the transistor (MN1) 160 is coupled to a first terminal of a current source 166 and the intersection of the capacitors (CA, CB) 162, 164. A second terminal of the current source 166 is grounded. A signal (e.g. voltage) may be inputted to a gate (G) terminal of the transistor (MN1) 160.

The Colpitts VCO 150 has a superior phase noise because the noise current from the active devices (e.g. transistor (MN1) 160 and/or current source 166) is injected into the LC tank of the inductor 152 and the capacitor 154, when the impulse sensitivity is low. However, the usage of Colpitts oscillator is confined due to higher start-up requirements and its single-ended nature. Therefore, higher power consumption is required to guarantee reliable start-up and the capacitor feedback configuration also reduces its tuning range.

In order to obtain immunity from common mode noise (i.e. reduce the effect of common mode noise), such as substrate and supply noise, a differential configuration may be provided by coupling two identical Colpitts oscillators with current switching technology or approach. Current switching reduces the noise perturbation at zero crossing of the output of the Colpitts oscillator and exhibits better noise performances. The use of the current switching technique may also lower the start up requirement, power consumption and headroom requirement. In addition, the negative resistance of the tail cross-coupled pair of transistors reuses the current from the oscillator core to enhance the small-signal loop gain, improving the start-up condition.

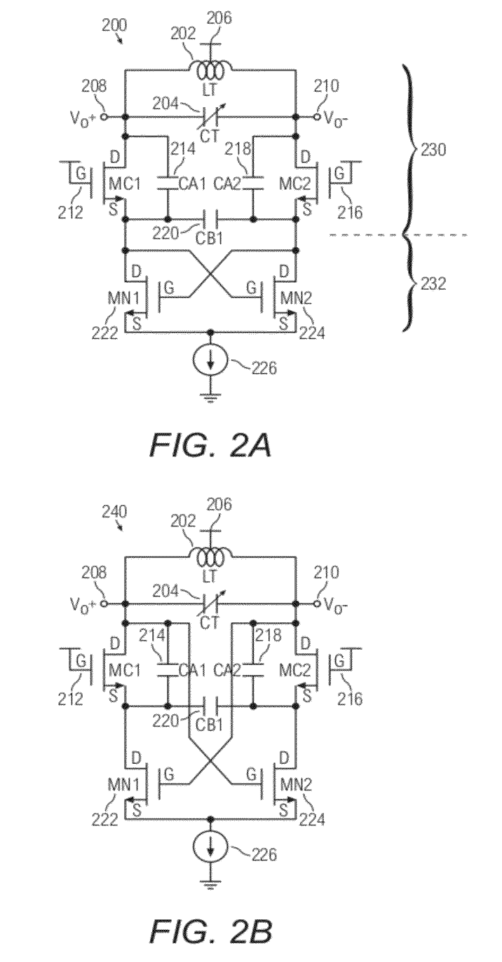

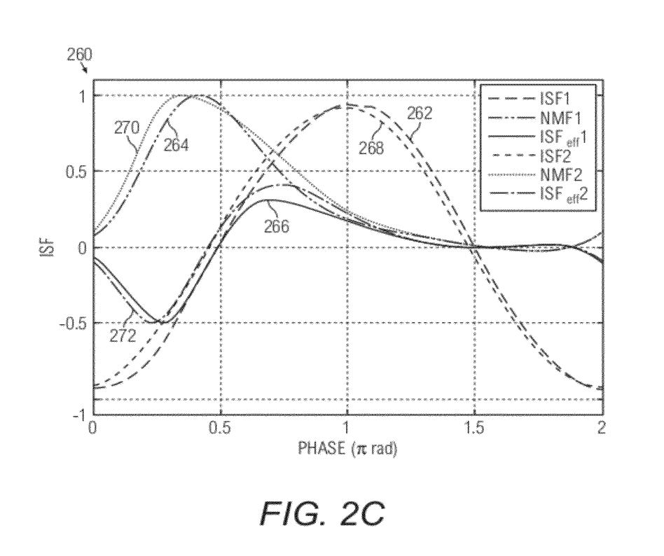

FIG. 2A shows a schematic of a differential Colpitts oscillator 200 with current switching. The differential Colpitts oscillator 200 is fully differential. The differential Colpitts oscillator 200 includes an LC circuit or LC tank for determining frequencies of the output signals, Vo+ and Vo−, including an inductor (LT) 202 in parallel with a capacitor (CT) 204. The capacitor (CT) 204 may be a variable capacitor. The inductor (LT) 202 may be coupled to an input terminal 206.

The first terminals of the inductor 202 and the capacitor 204 are coupled to each other and to a first output terminal (Vo+) 208 while the second terminals of the inductor 202 and the capacitor 204 are coupled to each other and to a second output terminal (Vo−) 210.

The differential Colpitts oscillator 200 includes a transistor (MC1) 212 with a capacitor (CA1) 214 having a first terminal coupled to a drain (D) terminal of the transistor (MC1) 212, and a second terminal coupled to a source (S) terminal of the transistor (MC1) 212. In addition, the differential Colpitts oscillator 200 includes a transistor (MC2) 216 with a capacitor (CA2) 218 having a first terminal coupled to a drain (D) terminal of the transistor (MC2) 216, and a second terminal coupled to a source (S) terminal of the transistor (MC2) 216. Each of the capacitor (CA1) 214 and the capacitor (CA2) 218 may have an at least substantially similar capacitance, C_{A}.

As shown in FIG. 2A, a capacitor (CB1) 220 is also coupled between the source (S) terminal of the transistor (MC1) 212 and the source (S) terminal of the transistor (MC2) 216. In various embodiments, as the differential Colpitts oscillator 200 is fully differential, the capacitor (CB1) 220 represents an equivalent capacitor of two capacitors (e.g. CB) in series. In other words, there are two capacitors in series between the source (S) terminal of the transistor (MC1) 212 and the source (S) terminal of the transistor (MC2) 216. Each of the two capacitors (e.g. CB) in series may have an at least substantially similar capacitance, C_{B}, such that the equivalent capacitor (CB1) 220 has an equivalent capacitance of C_{B}/2.

The inductor 202, the capacitors 204, 214, 218, 220, and the transistors 212, 216 may form an oscillator core 230 of the differential Colpitts oscillator 200. The capacitor (CA1) 214, the capacitor (CA2) 218 and the capacitor (CB1) 220 may form a capacitive divider. The potential or voltage between the drain (D) and source (S) terminals of the transistor (MC1) 212 is the same as the potential or voltage across the capacitor (CA1) 214. The potential or voltage between the drain (D) and source (S) terminals of the transistor (MC2) 216 is the same as the potential or voltage across the capacitor (CA2) 218. The potential or voltage between the source (S) terminal of the transistor (MC1) 212 and the source (S) terminal of the transistor (MC2) 216 is the same as the potential or voltage across the capacitor (CB1) 220.

The differential Colpitts oscillator 200 further includes a cross-coupled pair 232 of NMOS transistors 222, 224 for current switching. The drain (D) terminal of the transistor (MN1) 222 is coupled to the source (S) terminal of the transistor (MC1) 212 and the gate (G) terminal of the transistor (MN2) 224. The drain (D) terminal of the transistor (MN2) 224 is coupled to the source (S) terminal of the transistor (MC2) 216 and the gate (G) terminal of the transistor (MN1) 222. In other words, the gate (G) terminal of the transistor (MN2) 224 is coupled to the source (S) terminal of the transistor (MC1) 212, while the gate (G) terminal of the transistor (MN1) 222 is coupled to the source (S) terminal of the transistor (MC2) 216.

Furthermore, the source (S) terminals of the transistors (MN1, MN2) 222, 224 are coupled to each other and to a first terminal of a current source 226. The second terminal of the current source 226 is grounded. Signals (e.g. voltage) may be inputted to the respective gate (G) terminals of the transistors (MC1, MC2) 212, 216.

The in-phase relationship between the source and drain voltages at the respective source (S) and drain (D) terminals of the transistors (MC1) 212 and (MC2) 216 via the capacitive feedback, as shown in the architecture of the differential Colpitts oscillator 200 of FIG. 2A, illustrates that a topology or architecture of a differential Colpitts oscillator as illustrated in FIG. 2B may be provided in that the respective gate (G) terminals of the transistors (MN1) 222 and (MN2) 224 may be directly coupled to the VCO output terminals, respectively to the second output terminal (Vo−) 210 and the first output terminal (Vo+) 208, i.e. coupled to the respective drain (D) terminals of the transistors (MC2) 216 and (MC1) 214, instead of the respective source (S) terminals of the transistors (MC2) 216 and (MC1) 214.

FIG. 2B shows a schematic of a differential Colpitts oscillator 240, according to various embodiments. The differential Colpitts oscillator 240 is fully differential. The differential Colpitts oscillator 240 includes all the components of the differential Colpitts oscillator 200 of FIG. 2A and the descriptions relating to these components may be as described in the context of the differential Colpitts oscillator 200 and therefore will not be repeated. The respective components present in the differential Colpitts oscillator 200 and the differential Colpitts oscillator 240 are represented by the same respective reference numbers.

In addition, the arrangement of the various components of the differential Colpitts oscillator 240 is substantially the same as that of the differential Colpitts oscillator 200, except that in the differential Colpitts oscillator 240, the gate (G) terminal of the transistor (MN1) 222 is coupled, for example directly coupled, to the first terminal of the capacitor (CA2) 218 and the drain (D) terminal of the transistor (MC2) 216, and that the gate (G) terminal of the transistor (MN2) 224 is coupled, for example directly coupled, to the first terminal of the capacitor (CA1) 214 and the drain (D) terminal of the transistor (MC1) 212.

As illustrated in FIG. 2B, the gate (G) terminal of the transistor (MN1) 222 may also be coupled to the second terminal of the inductor 202, the second terminal of the capacitor 204 and the second output terminal (Vo−) 210, while the gate (G) terminal of the transistor (MN2) 224 may also be coupled to the first terminal of the inductor 202, the first terminal of the capacitor 204 and the first output terminal (Vo+) 208.

Descriptions relating to the arrangement of the components or the architecture of the differential Colpitts oscillator 240 that is similar to the differential Colpitts oscillator 200 may be as described in the context of the differential Colpitts oscillator 200 and therefore will not be repeated.

The enhanced loop gain of the differential Colpitts oscillator 240 may be expressed or approximated as the inverse of the capacitive divider factor, n, as given in Equation 1 below:

$$\frac{1}{n} = \frac{{C}_{A} + {C}_{B}}{{C}_{A}} . \qquad ( Equation 1 )$$

A faster switching of the transistor (MN1) 222 and the transistor (MN2) 224 may be obtained, thereby improving the phase noise characteristics of the differential Colpitts oscillator 240. In addition, directly connecting or coupling the respective gate (G) terminals of the transistor (MN1) 222 and the transistor (MN2) to the respective VCO outputs or output terminals relaxes the voltage headroom requirements.

Small-signal analysis of the differential Colpitts oscillator 200 (FIG. 2A) and the differential Colpitts oscillator 240 (FIG. 2B) will now be described.

The necessary start-up condition of oscillation for differential Colpitts oscillator needs to compensate for the loss in the LC tank, i.e. the negative impedance from the positive feedback should be larger than R_{P}, the equivalent parallel resistance at the resonant frequency. In a Colpitts oscillator, the capacitive divider, CA and CB, forms a positive feedback with the transistor, MN (e.g. FIG. 1B). In a differential Colpitts oscillator, a current switching cross-coupled pair of transistors (e.g. 232) is included under the Colpitts oscillator core (e.g. 230) to provide noise shaping and gₘ enhancement.

Based on the equivalent small-signal circuits model, the equivalent impedance looking into the drain terminals of the transistors 212, 216, of the main Colpitts oscillator 230, excluding the LC tank of inductor 202 and capacitor 204, contains a negative real part and may be calculated respectively by Equations 2 and 3 for the differential Colpitts oscillator 200 (FIG. 2A) and the differential Colpitts oscillator 240 (FIG. 2B).

$$\begin{matrix}Re [ {Z}_{a} ] = - \frac{{g}_{m 1} + {g}_{m 2} \frac{{C}_{A}}{{C}_{B}}}{{ω}^{2} {C}_{A} {C}_{B} + {g}_{m 2}^{2} \frac{{C}_{A}}{{C}_{B}}} & ( Equation 2 ) \\ Re [ {Z}_{a} ] = - \frac{{g}_{m 1} + {g}_{m 2} ( \frac{{C}_{A}}{{C}_{B}} + 1 + \frac{{g}_{m 1}^{2}}{{ω}^{2} {C}_{A} {C}_{B}} )}{{ω}^{2} {C}_{A} {C}_{B} + {g}_{m 2}^{2} ( \frac{{C}_{A}}{{C}_{B}} + \frac{2 {g}_{m 1}}{{g}_{m 2}} + \frac{{g}_{m 1}^{2}}{{ω}^{2} {C}_{A} {C}_{B}} )} & ( Equation 3 )\end{matrix}$$

where gₘ₁ and gₘ₂ are the transconductances of the MC and MN transistors, respectively, and w is the oscillation frequency.

For example, for the calculations looking into the drain terminal of the transistor (MC1) 212, gₘ₁ refers to the transconductance of the transistor (MC1) 212, gₘ₂ refers to the transconductance of the transistor (MN2) 224, and CA refers to the capacitance of the capacitor (CA1) 214. As the capacitor (CB1) 220 represents an equivalence of two capacitors in series, C_{B}, refers to the capacitance of each of the two capacitors in series such that the capacitor (CB1) 220 has an equivalent capacitance of C_{B}/2.

Based on the oscillation criteria, the circuit oscillates if the closed-loop transfer function goes to infinity at the oscillating frequency, w. The oscillation frequency, w, may be expressed as in Equation 4 by assuming gₘ₁L_{T}, gₘ₂L_{T}<<R_{P}(C_{A}+C_{B}):

$$ω = \frac{1}{\sqrt{LT ( {C}_{T} + \frac{{C}_{A} {C}_{B}}{{C}_{A} + {C}_{B}} )}} \qquad ( Equation 4 )$$

where L_{T} and C_{T} are the inductance and capacitance of the LC tank of inductor (LT) 202 and capacitor (CT) 204 respectively.

Therefore, the design equations for gₘ₁ and gₘ₂ result in Equations 5 and 6 for the differential Colpitts oscillator 200 (FIG. 2A) and the differential Colpitts oscillator 240 (FIG. 2B), respectively.

$$\begin{matrix}{g}_{m 1} {R}_{p} = \frac{{( {C}_{A} + {C}_{B} )}^{2} - {g}_{m 2} {R}_{p} {C}_{A}^{2}}{{C}_{A} {C}_{B}} . & ( Equation 5 ) \\ {g}_{m 1} {R}_{p} = \frac{{( {C}_{A} + {C}_{B} )}^{2} - {g}_{m 2} {R}_{p} {C}_{A} ( {C}_{A} + {C}_{B} )}{{C}_{A} {C}_{B}} . & ( Equation 6 )\end{matrix}$$

The minimum occurs when Equation 7 as given below is satisfied:

$${C}_{A} = \frac{1}{\sqrt{1 - {g}_{m 2} {R}_{p}}} {C}_{B} . \qquad ( Equation 7 )$$

Therefore, the minimum requirements for gₘ₁ are given as in Equations 8 and 9 for the differential Colpitts oscillator 200 (FIG. 2A) and the differential Colpitts oscillator 240 (FIG. 2B), respectively.

gₘ₁Rₚ≧2+2\sqrt{1−gₘ₂R_{P}} (Equation 8)

(gₘ₁+gₘ₂)Rₚ≧2+2\sqrt{1−gₘ₂R_{P}} (Equation 9).

If ignoring the effects of gₘ₂, the above Equations 8 and 9 may be simplified as Equation 10 below, which is the known expression of the conventional Colpitts oscillator when CA is equal to C_{B}.

gₘ₁Rₚ≧4 (Equation 10).

In contrast, conventional cross-coupled LC QVCOs exhibit gₘ₁Rₚ≧1.

Equations 8 and 9 illustrate that the requirement for gₘ₁ based on Equation 9 for the differential Colpitts oscillator 240 (FIG. 2B) is less than that based on Equation 8 for the differential Colpitts oscillator 200 (FIG. 2A), due to contribution of gₘ₂. In addition, the requirements for gₘ₁ for both the differential Colpitts oscillator 200 (FIG. 2A) and the differential Colpitts oscillator 240 (FIG. 2B) are even smaller compared to the conventional Colpitts oscillator or VCO based on Equation 10.

The effective impulse sensitivity functions of the differential Colpitts oscillator 200 (FIG. 2A) and the differential Colpitts oscillator 240 (FIG. 2B) will now be described.

The impulse sensitivity function (ISF) represents the time-varying sensitivity of oscillator phase to perturbations, while the noise modulation function (NMF) describes the modulation of the noise power spectrum with time for the noise source. The product of ISF and NMF results in the effective ISF.

FIG. 2C shows a plot 260 of the simulated effective impulse sensitivity functions of the differential Colpitts oscillators of the embodiments of FIGS. 2A and 2B. FIG. 2C shows the simulated results of the ISF (ISF1) 262, the NMF (NMF1) 264 and the effective ISF (ISF_{eff}1) 266 of the differential Colpitts oscillator 200 (FIG. 2A), and the simulated results of the ISF (ISF2) 268, the NMF (NMF2) 270 and the effective ISF (ISF_{eff}2) 272 of the differential Colpitts oscillator 240 (FIG. 2B).

As shown in FIG. 2C, the effective ISFs of the differential Colpitts oscillator or VCO topologies illustrated in FIGS. 2A and 2B show improved cyclostationary noise properties. The maximum noise generation instant (the peaks in the NMF results 264, 270) is substantially aligned with the respective oscillator's minimum sensitivity point (the minimum in the ISF results 262, 268 in the phase range of 0-0.5 rad) and hence the oscillators may achieve lower phase noises. In addition, the differential Colpitts oscillator 200 (FIG. 2A) and the differential Colpitts oscillator 240 (FIG. 2B) present smaller rms and dc values of their respective effective ISFs 266, 272, compared to that of conventional cross-coupled oscillators. Furthermore, the differential Colpitts oscillator 200 (FIG. 2A) and the differential Colpitts oscillator 240 (FIG. 2B) may have a symmetrical effective ISF, which may result in a reduction in the up-conversion of the low-frequency noise of the transistor.

Colpitts quadrature voltage controlled oscillators (QVCOs) will now be described. Various embodiments may provide low-power, low-phase-noise quadrature Colpitts voltage-controlled oscillators (QVCOs) based on the Colpitts oscillators. The low phase noise QVCOs of various embodiments are based on the superior phase noise Colpitts oscillators, which out-performs conventional cross-coupled VCOs. Various embodiments may further provide QVCOs with noise-shaping and transconductance enhancement to provide low power.

In various embodiments of the Colpitts QVCOs, the quadrature outputs may be achieved by coupling two differential Colpitts VCOs via the Colpitts oscillator cores, without additional coupling devices, and therefore also without additional biasing current consumption. The two differential Colpitts VCOs may be identical or symmetrical, for example in terms of topology or architecture. In various embodiments, one of the pair of differential Colpitts VCOs functions as an I-phase VCO while the other functions as a Q-phase VCO. The Colpitts QVCOs of various embodiments may have good phase noise and low power consumption, accurate quadrature signal generation without phase and phase noise trade-off, require less requirement for reliable start-up than a Colpitts VCO, and may be suitable for low power supply.

In various embodiments, as no additional devices are used, the QVCOs of various embodiments may provide a lower phase noise, a lower power consumption, a larger tuning range (TR) and a more accurate I/Q phase. In other words, the absence of additional coupling devices reduces the phase noise, increases the tuning range and minimises or eliminates the trade-off with the I/Q phase accuracy in the QVCOs of various embodiments. Therefore, the QVCOs of various embodiments may minimise or eliminate the design trade-off (for example in terms of injection, injection efficiency, tuning range and start-up reliability) to provide good phase noise, high tuning range, accurate I/Q phase and low power consumption. In addition, one or both of the two differential Colpitts VCOs may incorporate current switching technique or circuit, for example incorporating a cross-coupled pair of transistors.

In various embodiments, transconductance, gₘ, enhancement circuits, for example incorporating a cross-coupled pair of transistors, may be incorporated in the Colpitts VCO to provide additional negative gₘ to reduce power consumption to realize lower power consumption designs. In various embodiments, the current switching cross-coupled pair of transistors may also provide gₘ enhancement.

In various embodiments, the injection signals from the channels may inject into the oscillator core devices to cause injection lock and provide anti-phase injection for the QVCOs, without extra or additional coupling devices that are provided in conventional quadrature VCOs which degrade the phase noise. For example, the I (or Q) channel VCO signals inject into the Q (or I) channel oscillator core devices to cause anti-phase injection, and the Q (or I) channel VCO signals inject into the I (or Q) channel oscillator core devices with polarity swapping. In addition, the tail current may be split and coupled with a source degeneration capacitor to reduce flicker noise.

In various embodiments, the Colpitts VCO with current switching technique or circuit may reduce the start-up requirement, the power consumption and the minimum supply voltage. In addition, the Colpitts VCO further incorporating a gₘ boost circuit may further reduce the power consumption and the minimum supply voltage.

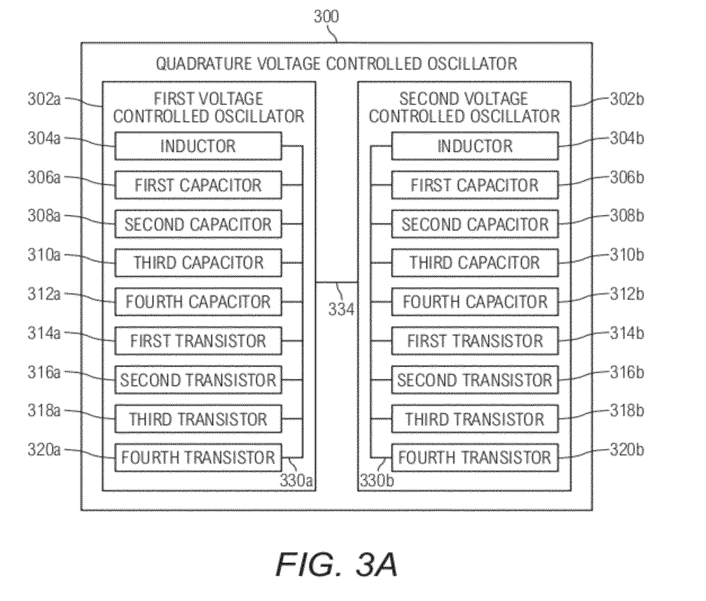

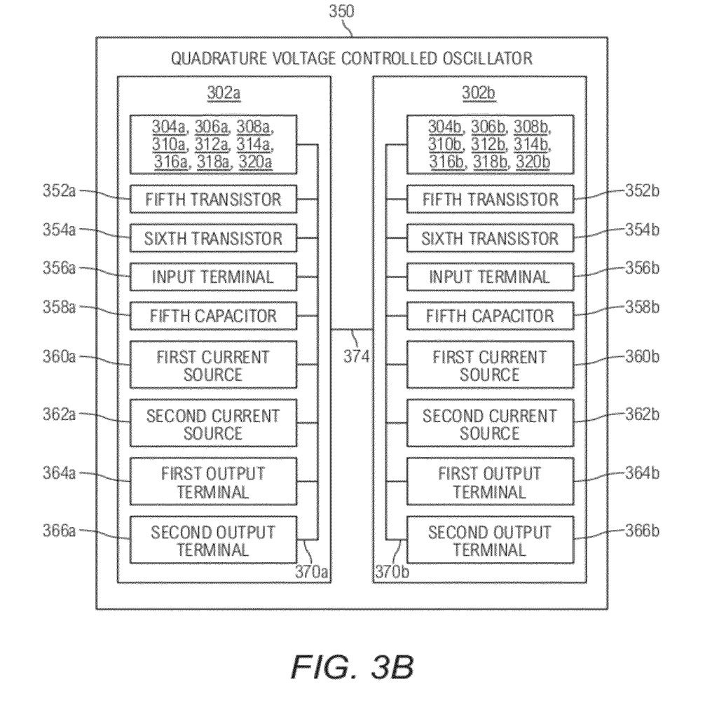

FIG. 3A shows a schematic block diagram of a quadrature voltage controlled oscillator (QVCO) 300, according to various embodiments. The quadrature voltage controlled oscillator 300 includes a first voltage controlled oscillator (VCO) 302a and a second voltage controlled oscillator (VCO) 302b respectively including an inductor (304a/304b) having a first terminal and a second terminal, a first capacitor (306a/306b), a second capacitor (308a/308b), a third capacitor (310a/310b) and a fourth capacitor (312a/312b) respectively including a first terminal and a second terminal, a first transistor (314a/314b), a second transistor (316a/316b), a third transistor (318a/318b) and a fourth transistor (320a/320b) respectively including a source terminal, a drain terminal and a gate terminal, wherein the first terminal of the inductor (304a/304b) is coupled to the first terminal of the first capacitor (306a/306b), and the second terminal of the inductor (304a/304b) is coupled to the second terminal of the first capacitor (306a/306b), wherein the drain terminal of the first transistor (314a/314b) is coupled to the first terminal of the inductor (304a/304b), the first terminal of the first capacitor (306a/306b), the first terminal of the second capacitor (308a/308b), and the gate terminal of the fourth transistor (320a/320b), wherein the drain terminal of the second transistor (316a/316b) is coupled to the second terminal of the inductor (304a/304b), the second terminal of the first capacitor (306a/306b), the first terminal of the third capacitor (310a/310b), and the gate terminal of the third transistor (318a/318b), wherein the source terminal of the first transistor (314a/314b) is coupled to the second terminal of the second capacitor (308a/308b), the drain terminal of the third transistor (318a/318b), and the first terminal of the fourth capacitor (312a/312b), wherein the source terminal of the second transistor (316a/316b) is coupled to the second terminal of the third capacitor (310a/310b), the drain terminal of the fourth transistor (320a/320b), and the second terminal of the fourth capacitor (312a/312b), wherein the gate terminal of the first transistor 314a of the first voltage controlled oscillator 302a is directly coupled to the first terminal of the inductor 304b of the second voltage controlled oscillator 302b, wherein the gate terminal of the second transistor 316a of the first voltage controlled oscillator 302a is directly coupled to the second terminal of the inductor 304b of the second voltage controlled oscillator 302b, wherein the gate terminal of the first transistor 314b of the second voltage controlled oscillator 302b is directly coupled to the second terminal of the inductor 304a of the first voltage controlled oscillator 302a, wherein the gate terminal of the second transistor 316b of the second voltage controlled oscillator 302b is directly coupled to the first terminal of the inductor 304a of the first voltage controlled oscillator 302a.

In other words, the quadrature voltage controlled oscillator 300 includes a first voltage controlled oscillator 302a and a second voltage controlled oscillator 302b. The first voltage controlled oscillator 302a includes an inductor 304a having a first terminal and a second terminal, a first capacitor 306a, a second capacitor 308a, a third capacitor 310a and a fourth capacitor 312a respectively including a first terminal and a second terminal, a first transistor 314a, a second transistor 316a, a third transistor 318a and a fourth transistor 320a respectively including a source terminal, a drain terminal and a gate terminal, wherein the first terminal of the inductor 304a is coupled to the first terminal of the first capacitor 306a, and the second terminal of the inductor 304a is coupled to the second terminal of the first capacitor 306a, wherein the drain terminal of the first transistor 314a is coupled to the first terminal of the inductor 304a, the first terminal of the first capacitor 306a, the first terminal of the second capacitor 308a, and the gate terminal of the fourth transistor 320a, wherein the drain terminal of the second transistor 316a is coupled to the second terminal of the inductor 304a, the second terminal of the first capacitor 306a, the first terminal of the third capacitor 310a, and the gate terminal of the third transistor 318a, wherein the source terminal of the first transistor 314a is coupled to the second terminal of the second capacitor 308a, the drain terminal of the third transistor 318a, and the first terminal of the fourth capacitor 312a, wherein the source terminal of the second transistor 316a is coupled to the second terminal of the third capacitor 310a, the drain terminal of the fourth transistor 320a, and the second terminal of the fourth capacitor 312a. The line represented as 330a is illustrated to show the relationship among the different components, which may include electrical coupling and/or mechanical coupling.

Similar to the first voltage controlled oscillator 302a, the second voltage controlled oscillator 302b includes an inductor 304b having a first terminal and a second terminal, a first capacitor 306b, a second capacitor 308b, a third capacitor 310b and a fourth capacitor 312b respectively including a first terminal and a second terminal, a first transistor 314b, a second transistor 316b, a third transistor 318b and a fourth transistor 320b respectively including a source terminal, a drain terminal and a gate terminal, wherein the first terminal of the inductor 304b is coupled to the first terminal of the first capacitor 306b, and the second terminal of the inductor 304b is coupled to the second terminal of the first capacitor 306b, wherein the drain terminal of the first transistor 314b is coupled to the first terminal of the inductor 304b, the first terminal of the first capacitor 306b, the first terminal of the second capacitor 308b, and the gate terminal of the fourth transistor 320b, wherein the drain terminal of the second transistor 316b is coupled to the second terminal of the inductor 304b, the second terminal of the first capacitor 306b, the first terminal of the third capacitor 310b, and the gate terminal of the third transistor 318b, wherein the source terminal of the first transistor 314b is coupled to the second terminal of the second capacitor 308b, the drain terminal of the third transistor 318b, and the first terminal of the fourth capacitor 312b, wherein the source terminal of the second transistor 316b is coupled to the second terminal of the third capacitor 310b, the drain terminal of the fourth transistor 320b, and the second terminal of the fourth capacitor 312b. The line represented as 330b is illustrated to show the relationship among the different components, which may include electrical coupling and/or mechanical coupling.

Therefore, the first voltage controlled oscillator 302a and the second voltage controlled oscillator 302b are identical and have the same architecture, topology or arrangement. In FIG. 3A, the line represented as 334 is illustrated to show the relationship between the first voltage controlled oscillator 302a and the second voltage controlled oscillator 302b, which may include electrical coupling and/or mechanical coupling.

Each of the first voltage controlled oscillator 302a and the second voltage controlled oscillator 302b is a fully differential oscillator. Using the first voltage controlled oscillator 302a as an example, each of the second capacitor 308a and the third capacitor 310a may have an at least substantially similar capacitance, e.g. C_{A}. In various embodiments, as the first voltage controlled oscillator 302a is fully differential, the fourth capacitor 312a represents an equivalent capacitor of two capacitors in series. In other words, there are two capacitors in series between the source (S) terminal of the first transistor 314a and the source (S) terminal of the second transistor 316a. Each of the two capacitors in series may have an at least substantially similar capacitance, e.g. C_{B}, such that the fourth capacitor 312a has an equivalent capacitance of e.g. C_{B}/2. This similarly applied to the second voltage controlled oscillator 302b, with respect to the second capacitor 308b, the third capacitor 310b and the fourth capacitor 312b.

FIG. 3B shows a schematic block diagram of a quadrature voltage controlled oscillator (QVCO) 350, according to various embodiments. The quadrature voltage controlled oscillator 350 includes a first voltage controlled oscillator (VCO) 302a and a second voltage controlled oscillator (VCO) 302b, which may be similar to the embodiment as described in the context of FIG. 3A.

The first voltage controlled oscillator 302a of the quadrature voltage controlled oscillator 350 includes an inductor 304a having a first terminal and a second terminal, a first capacitor 306a, a second capacitor 308a, a third capacitor 310a and a fourth capacitor 312a respectively including a first terminal and a second terminal, and a first transistor 314a, a second transistor 316a, a third transistor 318a and a fourth transistor 320a respectively including a source terminal, a drain terminal and a gate terminal, where these components may be coupled or arranged similar to the embodiment as described in the context of FIG. 3A.

The second voltage controlled oscillator 302b of the quadrature voltage controlled oscillator 350 includes an inductor 304b having a first terminal and a second terminal, a first capacitor 306b, a second capacitor 308b, a third capacitor 310b and a fourth capacitor 312b respectively including a first terminal and a second terminal, a first transistor 314b, a second transistor 316b, a third transistor 318b and a fourth transistor 320b respectively including a source terminal, a drain terminal and a gate terminal, where these components may be coupled or arranged similar to the embodiment as described in the context of FIG. 3A.

The first voltage controlled oscillator 302a of the quadrature voltage controlled oscillator 350 may further include a fifth transistor 352a and a sixth transistor 354a respectively including a source terminal, a drain terminal and a gate terminal, an input terminal 356a, wherein the source terminal of the fifth transistor 352a is coupled to the source terminal of the sixth transistor 354a, wherein the gate terminal of the fifth transistor 352a is coupled to the drain terminal of the sixth transistor 354a, the second terminal of the inductor 304a of the first voltage controlled oscillator 302a and a second output terminal 366a of the first voltage controlled oscillator 302a, wherein the drain terminal of the fifth transistor 352a is coupled to the gate terminal of the sixth transistor 354a, the first terminal of the inductor 340a of the first voltage controlled oscillator 302a and a first output terminal 364a of the first voltage controlled oscillator 302a, wherein the input terminal 356a is coupled between the source terminal of the fifth transistor 352a and the source terminal of the sixth transistor 354a.

The first voltage controlled oscillator 302a of the quadrature voltage controlled oscillator 350 may further include a fifth capacitor 358a including a first terminal and a second terminal, a first current source 360a and a second current source 362a respectively including a first terminal (e.g. an input terminal) and a second terminal (e.g. an output terminal), wherein the first terminal of the fifth capacitor 358a is coupled to the source terminal of the third transistor 318a and the first terminal of the first current source 360a, wherein the second terminal of the fifth capacitor 358a is coupled to the source terminal of the fourth transistor 320a and the first terminal of the second current source 362a, wherein the second terminal of the first current source 360a and the second terminal of the second current source 362a are coupled to ground.

The second voltage controlled oscillator 302b of the quadrature voltage controlled oscillator 350 may further include a fifth transistor 352b and a sixth transistor 354b respectively including a source terminal, a drain terminal and a gate terminal, an input terminal 356b, wherein the source terminal of the fifth transistor 352b is coupled to the source terminal of the sixth transistor 354b, wherein the gate terminal of the fifth transistor 352b is coupled to the drain terminal of the sixth transistor 354b, the second terminal of the inductor 304b of the second voltage controlled oscillator 302b and a second output terminal 366b of the second voltage controlled oscillator 302b, wherein the drain terminal of the fifth transistor 352b is coupled to the gate terminal of the sixth transistor 354b, the first terminal of the inductor 304b of the second voltage controlled oscillator 302b and a first output terminal 364b of the second voltage controlled oscillator 302b, wherein the input terminal 356b is coupled between the source terminal of the fifth transistor 352b and the source terminal of the sixth transistor 354b.

The second voltage controlled oscillator 302b of the quadrature voltage controlled oscillator 350 may further include a fifth capacitor 358b including a first terminal and a second terminal, a first current source 360b and a second current source 362b respectively including a first terminal (e.g. an input terminal) and a second terminal (e.g. an output terminal), wherein the first terminal of the fifth capacitor 358b is coupled to the source terminal of the third transistor 318b and the first terminal of the first current source 360b, wherein the second terminal of the fifth capacitor 358b is coupled to the source terminal of the fourth transistor 320b and the first terminal of the second current source 362b, wherein the second terminal of the first current source 360b and the second terminal of the second current source 362b are coupled to ground.

The line represented as 370a is illustrated to show the relationship among the different components of the first voltage controlled oscillator 302a, which may include electrical coupling and/or mechanical coupling, while the line represented as 370b is illustrated to show the relationship among the different components of the second voltage controlled oscillator 302b, which may include electrical coupling and/or mechanical coupling. In addition, the line represented as 374 is illustrated to show the relationship between the first voltage controlled oscillator 302a and the second voltage controlled oscillator 302b, which may include electrical coupling and/or mechanical coupling.

In the context of various embodiments, the first voltage controlled oscillator 302a of the quadrature voltage controlled oscillator 300 or quadrature voltage controlled oscillator 350 may be an in-phase voltage controlled oscillator, and the second voltage controlled oscillator 302b of the quadrature voltage controlled oscillator 300 or quadrature voltage controlled oscillator 350 may be a quadrature-phase voltage controlled oscillator.

In the context of various embodiments, the first capacitor 306a of the first voltage controlled oscillator 302a of the quadrature voltage controlled oscillator 300 or quadrature voltage controlled oscillator 350 may be a variable capacitor, and/or the first capacitor 306b of the second voltage controlled oscillator 302b of the quadrature voltage controlled oscillator 300 or quadrature voltage controlled oscillator 350 may be a variable capacitor.

In the context of various embodiments, the gate terminal of the first transistor 314a of the first voltage controlled oscillator 302a may also be coupled or directly coupled to the first output terminal 364b of the second voltage controlled oscillator 302b.

In the context of various embodiments, the gate terminal of the second transistor 316a of the first voltage controlled oscillator 302a may also be coupled or directly coupled to the second output terminal 366b of the second voltage controlled oscillator 302b.

In the context of various embodiments, the gate terminal of the first transistor 314b of the second voltage controlled oscillator 302b may also be coupled or directly coupled to the second output terminal 366a of the first voltage controlled oscillator 302a.

In the context of various embodiments, the gate terminal of the second transistor 316b of the second voltage controlled oscillator 302b may also be coupled or directly coupled to the first output terminal 364a of the first voltage controlled oscillator 302a.

In the context of various embodiments, each of the first transistor (314a/314b), the second transistor (316a/316b), the third transistor (318a/318b), the fourth transistor (320a/320b), the fifth transistor (352a/352b) and the sixth transistor (354a/354b) may be a field effect transistor, e.g. a metal-oxide-semiconductor field-effect transistor (MOSFET) (e.g. N-channel MOSFET), a metal-insulator-semiconductor field-effect transistor (MISFET) or a metal semiconductor field effect transistor (MESFET).

In the context of various embodiments, the term “voltage controlled oscillator” or “VCO” refers to an oscillator configured to vary its oscillation frequency by means of a voltage input.

In the context of various embodiments, the term “quadrature voltage controlled oscillator” or “QVCO” refers to an oscillator including a pair of interconnected VCOs configured to output a plurality of signals having different phases.

In the context of various embodiments, a reference to the term “coupled” with regard to two components may include a reference to “directly coupled” or “indirectly coupled”, e.g. including one or more other components (e.g. resistor and/or inductor and/or capacitor) connected therebetween the two components.

Various embodiments may provide a quadrature voltage controlled oscillator (QVCO) based on the differential Colpitts VCO (e.g the differential Colpitts oscillator 200 (FIG. 2A) or the differential Colpitts oscillator 240 (FIG. 2B)) with its corresponding improved phase noise performance. The QVCOs of various embodiments may be, for example, based on a pair of identical differential Colpitts oscillators 200 (FIG. 2A) or a pair of identical differential Colpitts oscillators 240 (FIG. 2B). Achieving quadrature operation from two identical or symmetrical oscillators requires coupling between the two identical oscillators, where in the differential Colpitts VCOs 200, 240, for example, the transistors (MC1) 212 and (MC2) 216 may be directly used as the coupling devices, without adding additional coupling devices similar to those included in conventional coupled quadrature VCOs.

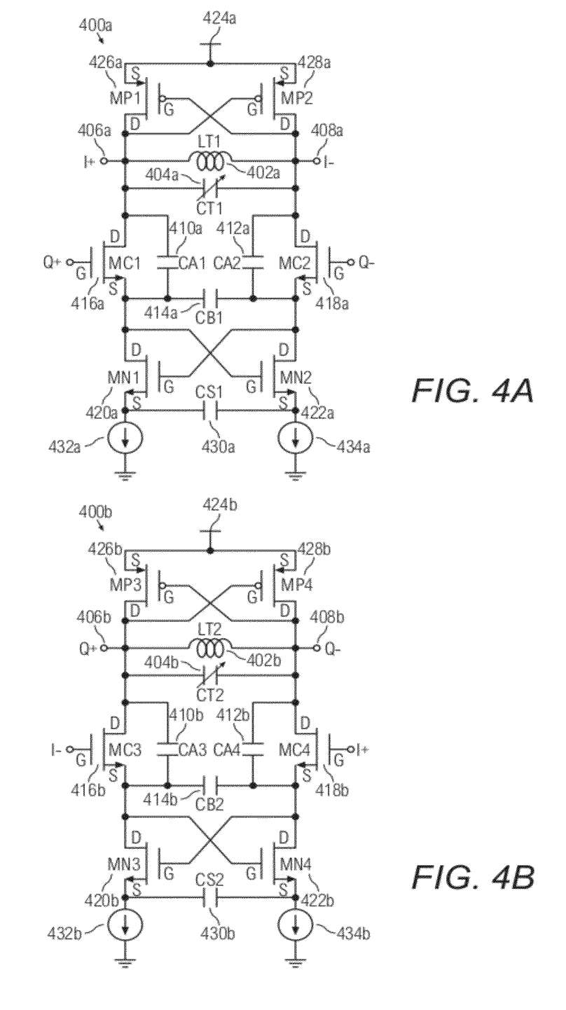

FIGS. 4A and 4B show a schematic of a Colpitts quadrature voltage controlled oscillator (referred to as “QVCO1”), according to various embodiments. The Colpitts QVCO includes a pair of identical differential Colpitts oscillators or VCOs, i.e. a first VCO 400a (FIG. 4A) and a second VCO 400b (FIG. 4B). Each of the first VCO 400a and the second VCO 400b is a fully differential oscillator.

As shown in FIG. 4A, the first VCO 400a includes an LC tank including an inductor (LT1) 402a and a capacitor (CT1) (e.g. first capacitor) 404a. The LC tank is configured to determine frequencies of the in-phase output signals I+ and I−. Each of the inductor 402a and the capacitor 404a has a first terminal and a second terminal. The first terminal of the inductor 402a is coupled to the first terminal of the capacitor 404a and the second terminal of the inductor 402a is coupled to the second terminal of the capacitor 404a. The respective first terminals of the inductor 402a and the capacitor 404a are also coupled to a first output terminal 406a of the first VCO 400a, while the respective second terminals of the inductor 402a and the capacitor 404a are also coupled to a second output terminal 408a of the first VCO 400a. The capacitor 404a may be a variable capacitor.

The first VCO 400a further includes a capacitor (CA1) (e.g. second capacitor) 410a, a capacitor (CA2) (e.g. third capacitor) 412a and a capacitor (CB1) (e.g. fourth capacitor) 414a respectively having a first terminal and a second terminal. The capacitors 410a, 412a, 414a form a capacitive divider.

The first VCO 400a further includes a transistor (MC1) (e.g. first transistor) 416a, a transistor (MC2) (e.g. second transistor) 418a, a transistor (MN1) (e.g. third transistor) 420a and a transistor (MN2) (e.g. fourth transistor) 422a respectively having a source (S) terminal, a drain (D) terminal and a gate (G) terminal. The transistors 420a, 422a form a current switching cross-coupled pair of transistors. The cross-coupled pair of NMOS transistors 420a, 422a are also configured to provide noise shaping and gₘ enhancement. The inductor 402a, the capacitors 404a, 410a, 412a, 414a, and the transistors 416a, 418a may form an oscillator core of the first VCO 400a.

As shown in FIG. 4A, the capacitor 410a is coupled across or between the source (S) terminal and the drain (D) terminal of the transistor 416a, e.g. the first terminal of the capacitor 410a is coupled to the drain (D) terminal of the transistor 416a and the second terminal of the capacitor 410a is coupled to the source (S) terminal of the transistor 416a.

The capacitor 412a is coupled across or between the source (S) terminal and the drain (D) terminal of the transistor 418a, e.g. the first terminal of the capacitor 412a is coupled to the drain (D) terminal of the transistor 418a and the second terminal of the capacitor 412a is coupled to the source (S) terminal of the transistor 418a.

The capacitor 414a is coupled between the capacitors 410a, 412a, and also coupled between the respective source (S) terminals of the transistors 416a, 418a, e.g. the first terminal of the capacitor 414a is coupled to the source (S) terminal of the transistor 416a and the second terminal of the capacitor 414a is coupled to the source (S) terminal of the transistor 418a.

As shown in FIG. 4A, the drain (D) terminal of the transistor 416a is coupled to the first terminal of the inductor 402a, the first terminal of the capacitor 404a and the first terminal of the capacitor 410a. The drain (D) terminal of the transistor 416a is also coupled to the first output terminal 406a. The drain (D) terminal of the transistor 418a is coupled to the second terminal of the inductor 402a, the second terminal of the capacitor 404a and the first terminal of the capacitor 412a. The drain (D) terminal of the transistor 418a is also coupled to the second output terminal 408a.

As shown in FIG. 4A, the source (S) terminal of the transistor 416a is coupled to the second terminal of the capacitor 410a, the drain (D) terminal of the transistor 420a, the first terminal of the capacitor 414a and the gate (G) terminal of the transistor 422a. The source (S) terminal of the transistor 418a is coupled to the second terminal of the capacitor 412a, the drain (D) terminal of the transistor 422a, the second terminal of the capacitor 414a and the gate (G) terminal of the transistor 420a.

The first VCO 400a further includes an input terminal 424a, and a transistor (MP1) (e.g. fifth transistor) 426a and a transistor (MP2) (e.g. sixth transistor) 428a respectively having a source terminal, a drain terminal and a gate terminal. The source (S) terminal of the transistor 426a is coupled to the source (S) terminal of the transistor 428a, and the input terminal 424a is coupled between the source (S) terminal of the transistor 426a and the source (S) terminal of the transistor 428a.

The transistors 426a, 428a are PMOS, and form a cross-coupled pair of PMOS transistors. The gate terminal of the transistor 426a is coupled to the drain (D) terminal of the transistor 428a, the second terminal of the inductor 402a and the second output terminal 408a. The drain (D) terminal of the transistor 426a is coupled to the gate (G) terminal of the transistor 428a, the first terminal of the inductor 402a and the first output terminal 406a. As the Colpitts quadrature voltage controlled oscillator (“QVCO1”) of various embodiments does not require additional injection devices, and may favour a low supply voltage, incorporating the cross-coupled pair of PMOS transistors 426a, 428a may provide further gₘ enhancement through current re-using technique. However, it should be appreciated that the cross-coupled pair of PMOS transistors 426a, 428a may be optionally provided in the first VCO 400a.

The first VCO 400a further includes a capacitor (CS1) (e.g. fifth capacitor) 430a having a first terminal and a second terminal, a current source (e.g. first current source) 432a and a current source (e.g. second current source) 434a respectively having a first terminal (e.g. an input terminal) and a second terminal (e.g. an output terminal). The capacitor (CS1) 430a may be a source degeneration capacitor to reduce flicker noise. The first terminal of the capacitor 430a is coupled to the source (S) terminal of the transistor 420a and the first terminal of the current source 432a. The second terminal of the capacitor 430a is coupled to the source (S) terminal of the transistor 422a and the first terminal of the current source 434a. The second terminal of the current source 432a and the second terminal of the current source 434a are coupled to ground. Each of the current source 432a and the current source 434a are configured to supply a constant current to the first VCO 400a.

Each of the capacitor (CA1) 410a and the capacitor (CA2) 412a may have an at least substantially similar capacitance, C_{A}. In various embodiments, as the first VCO 400a is fully differential, the capacitor (CB1) 414a represents an equivalent capacitor of two capacitors (e.g. CB) in series. In other words, there are two capacitors in series between the source (S) terminal of the transistor (MC1) 416a and the source (S) terminal of the transistor (MC2) 418a. Each of the two capacitors (e.g. CB) in series may have an at least substantially similar capacitance, C_{B}, such that the equivalent capacitor CB1) 414a has an equivalent capacitance of C_{B}/2. In addition, the capacitor (CS1) 430a has a capacitance, C_{S}.

As shown in FIG. 4B, the second VCO 400b includes an LC tank including an inductor (LT2) 402b and a capacitor (CT2) (e.g. first capacitor) 404b. The LC tank is configured to determine frequencies of the quadrature-phase output signals Q+ and Q−. Each of the inductor 402b and the capacitor 404b has a first terminal and a second terminal. The first terminal of the inductor 402b is coupled to the first terminal of the capacitor 404b and the second terminal of the inductor 402b is coupled to the second terminal of the capacitor 404b. The respective first terminals of the inductor 402b and the capacitor 404b are also coupled to a first output terminal 406b of the second VCO 400b, while the respective second terminals of the inductor 402b and the capacitor 404b are also coupled to a second output terminal 408b of the second VCO 400b. The capacitor 404b may be a variable capacitor.

The second VCO 400b further includes a capacitor (CA3) (e.g. second capacitor) 410b, a capacitor (CA4) (e.g. third capacitor) 412b and a capacitor (CB2) (e.g. fourth capacitor) 414b respectively having a first terminal and a second terminal. The capacitors 410b, 412b, 414b form a capacitive divider.

The second VCO 400b further includes a transistor (MC3) (e.g. first transistor) 416b, a transistor (MC4) (e.g. second transistor) 418b, a transistor (MN3) (e.g. third transistor) 420b and a transistor (MN4) (e.g. fourth transistor) 422b respectively having a source (S) terminal, a drain (D) terminal and a gate (G) terminal. The transistors 420b, 422b are NMOS, and form a current switching cross-coupled pair of NMOS transistors. The cross-coupled pair of transistors 420b, 422b are also configured to provide noise shaping and gₘ enhancement. The inductor 402b, the capacitors 404b, 410b, 412b, 414b, and the transistors 416b, 418b may form an oscillator core of the second VCO 400b.

As shown in FIG. 4B, the capacitor 410b is coupled across or between the source (S) terminal and the drain (D) terminal of the transistor 416b, e.g. the first terminal of the capacitor 410b is coupled to the drain (D) terminal of the transistor 416b and the second terminal of the capacitor 410b is coupled to the source (S) terminal of the transistor 416b.

The capacitor 412b is coupled across or between the source (S) terminal and the drain (D) terminal of the transistor 418b, e.g. the first terminal of the capacitor 412b is coupled to the drain (D) terminal of the transistor 418b and the second terminal of the capacitor 412b is coupled to the source (S) terminal of the transistor 418b.

The capacitor 414b is coupled between the capacitors 410b, 412b, and also coupled between the respective source (S) terminals of the transistors 416b, 418b, e.g. the first terminal of the capacitor 414b is coupled to the source (S) terminal of the transistor 416b and the second terminal of the capacitor 414b is coupled to the source (S) terminal of the transistor 418b.

As shown in FIG. 4B, the drain (D) terminal of the transistor 416b is coupled to the first terminal of the inductor 402b, the first terminal of the capacitor 404b and the first terminal of the capacitor 410b. The drain (D) terminal of the transistor 416b is also coupled to the first output terminal 406b. The drain (D) terminal of the transistor 418b is coupled to the second terminal of the inductor 402b, the second terminal of the capacitor 404b and the first terminal of the capacitor 412b. The drain (D) terminal of the transistor 418b is also coupled to the second output terminal 408b.

As shown in FIG. 4B, the source (S) terminal of the transistor 416b is coupled to the second terminal of the capacitor 410b, the drain (D) terminal of the transistor 420b, the first terminal of the capacitor 414b and the gate (G) terminal of the transistor 422b. The source (S) terminal of the transistor 418b is coupled to the second terminal of the capacitor 412b, the drain (D) terminal of the transistor 422b, the second terminal of the capacitor 414b and the gate (G) terminal of the transistor 420b.

The second VCO 400b further includes an input terminal 424b, and a transistor (MP3) (e.g. fifth transistor) 426b and a transistor (MP4) (e.g. sixth transistor) 428b respectively having a source terminal, a drain terminal and a gate terminal. The source (S) terminal of the transistor 426b is coupled to the source (S) terminal of the transistor 428b, and the input terminal 424b is coupled between the source (S) terminal of the transistor 426b and the source (S) terminal of the transistor 428b.

The transistors 426b, 428b are PMOS, and form a cross-coupled pair of PMOS transistors. The gate (G) terminal of the transistor 426b is coupled to the drain (D) terminal of the transistor 428b, the second terminal of the inductor 402b and the second output terminal 408b. The drain (D) terminal of the transistor 426b is coupled to the gate (G) terminal of the transistor 428b, the first terminal of the inductor 402b and the first output terminal 406b. Similar to the cross-coupled pair of PMOS transistors 426a, 428a of the first VCO 400a, the cross-coupled pair of PMOS transistors 426b, 428b may be optionally provided in the second VCO 400b to provide further gₘ enhancement through current re-using technique.

The second VCO 400b further includes a capacitor (CS2) (e.g. fifth capacitor) 430b having a first terminal and a second terminal, a current source (e.g. first current source) 432b and a current source (e.g. second current source) 434b respectively having a first terminal (e.g. an input terminal) and a second terminal (e.g. an output terminal). The capacitor (CS2) 430b may be a source degeneration capacitor to reduce flicker noise. The first terminal of the capacitor 430b is coupled to the source (S) terminal of the transistor 420b and the first terminal of the current source 432b. The second terminal of the capacitor 430b is coupled to the source (S) terminal of the transistor 422b and the first terminal of the current source 434b. The second terminal of the current source 432b and the second terminal of the current source 434b are coupled to ground. Each of the current source 432b and the current source 434b are configured to supply a constant current to the second VCO 400b.

Each of the capacitor (CA3) 410b and the capacitor (CA4) 412b may have an at least substantially similar capacitance, C_{A}. In various embodiments, as the second VCO 400b is fully differential, the capacitor (CB2) 414b represents an equivalent capacitor of two capacitors (e.g. CB) in series. In other words, there are two capacitors in series between the source (S) terminal of the transistor (MC3) 416b and the source (S) terminal of the transistor (MC4) 418b. Each of the two capacitors (e.g. CB) in series may have an at least substantially similar capacitance, C_{B}, such that the equivalent capacitor (CB2) 414b has an equivalent capacitance of C_{B}/2. In addition, the capacitor (CS2) 430b has a capacitance, C_{S}.

The first VCO 400a is an in-phase (I-phase) VCO, and the second VCO 400b is a quadrature-phase (Q-phase) VCO. The first output terminal 406a and the second output terminal 408a of the first VCO 400a respectively output a positive in-phase output signal (I+) and a negative in-phase output signal (I−). The first output terminal 406b and the second output terminal 408b of the second VCO 400b respectively output a positive quadrature-phase output signal (Q+) and a negative quadrature-phase output signal (Q−).

As shown in FIGS. 4A and 4B, the gate (G) terminal of the transistor 416a of the first VCO 400a is directly coupled to the first terminal of the inductor 402b of the second VCO 400b. The gate (G) terminal of the transistor 416a of the first VCO 400a is also directly coupled to the first output terminal (Q+) 406b of the second VCO 400b.

The gate (G) terminal of the transistor 418a of the first VCO 400a is directly coupled to the second terminal of the inductor 402b of the second VCO 400b. The gate (G) terminal of the transistor 418a of the first VCO 400a is also directly coupled to the second output terminal (Q−) 408b of the second VCO 400b.

The gate (G) terminal of the transistor 416b of the second VCO 400b is directly coupled to the second terminal of the inductor 402a of the first VCO 400a. The gate (G) terminal of the transistor 416b of the second VCO 400b is also directly coupled to the second output terminal (I−) 408a of the first VCO 400a.

The gate (G) terminal of the transistor 418b of the second VCO 400b is directly coupled to the first terminal of the inductor 402a of the first VCO 400a. The gate (G) terminal of the transistor 418b of the second VCO 400b is also directly coupled to the first output terminal (I+) 406a of the first VCO 400a.

Therefore, the I channel VCO signals inject into the Q channel oscillator core devices to cause anti-phase injection, and similarly the Q channel VCO signals inject into the I channel oscillator core devices, but with polarity swapping. For example, the gate (G) terminal of the transistor 416a of the first VCO 400a is biased with positive polarity, while the gate (G) terminal of the transistor 416b of the second VCO 400b is biased with negative polarity. Accordingly, the first VCO 400a and the second VCO 400b are interconnected or coupled with each other to constitute a feedback loop.

Each of the transistors 416a, 418a, 416b, 418b, may be an N-channel MOSFET (NMOS).

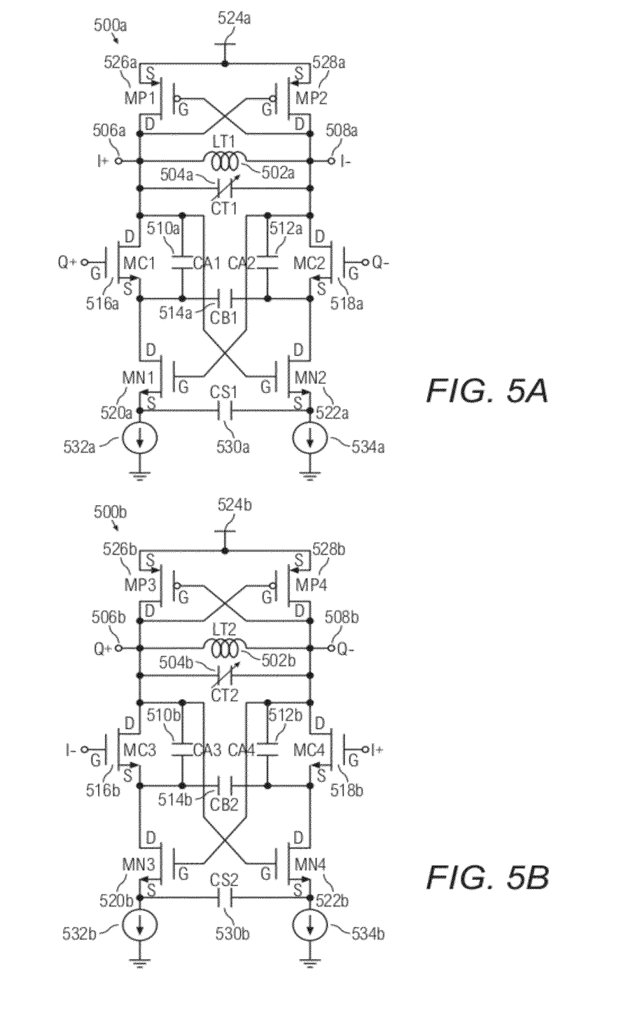

FIGS. 5A and 5B show a schematic of a Colpitts quadrature voltage controlled oscillator (referred to as “QVCO2”), according to various embodiments. The Colpitts QVCO includes a pair of identical differential Colpitts oscillators or VCOs, i.e. a first VCO 500a (FIG. 5A) and a second VCO 500b (FIG. 5B). Each of the first VCO 500a and the second VCO 500b is a fully differential oscillator.

As shown in FIG. 5A, the first VCO 500a includes an LC tank including an inductor (LT1) 502a and a capacitor (CT1) (e.g. first capacitor) 504a. The LC tank is configured to determine frequencies of the in-phase output signals I+ and I−. Each of the inductor 502a and the capacitor 504a has a first terminal and a second terminal. The first terminal of the inductor 502a is coupled to the first terminal of the capacitor 504a and the second terminal of the inductor 502a is coupled to the second terminal of the capacitor 504a. The respective first terminals of the inductor 502a and the capacitor 504a are also coupled to a first output terminal 506a of the first VCO 500a, while the respective second terminals of the inductor 502a and the capacitor 504a are also coupled to a second output terminal 508a of the first VCO 500a. The capacitor 504a may be a variable capacitor.

The first VCO 500a further includes a capacitor (CA1) (e.g. second capacitor) 510a, a capacitor (CA2) (e.g. third capacitor) 512a and a capacitor (CB1) (e.g. fourth capacitor) 514a respectively having a first terminal and a second terminal. The capacitors 510a, 512a, 514a form a capacitive divider.

The first VCO 500a further includes a transistor (MC1) (e.g. first transistor) 516a, a transistor (MC2) (e.g. second transistor) 518a, a transistor (MN1) (e.g. third transistor) 520a and a transistor (MN2) (e.g. fourth transistor) 522a respectively having a source (S) terminal, a drain (D) terminal and a gate (G) terminal. The transistors 520a, 522a are NMOS, and form a current switching cross-coupled pair of NMOS transistors. The cross-coupled pair of transistors 520a, 522a are also configured to provide noise shaping and gₘ enhancement. The inductor 502a, the capacitors 504a, 510a, 512a, 514a, and the transistors 516a, 518a may form an oscillator core of the first VCO 500a.

As shown in FIG. 5A, the capacitor 510a is coupled across or between the source (S) terminal and the drain (D) terminal of the transistor 516a, e.g. the first terminal of the capacitor 510a is coupled to the drain (D) terminal of the transistor 516a and the second terminal of the capacitor 510a is coupled to the source (S) terminal of the transistor 516a.

The capacitor 512a is coupled across or between the source (S) terminal and the drain (D) terminal of the transistor 518a, e.g. the first terminal of the capacitor 512a is coupled to the drain (D) terminal of the transistor 518a and the second terminal of the capacitor 512a is coupled to the source (S) terminal of the transistor 518a.

The capacitor 514a is coupled between the capacitors 510a, 512a, and also coupled between the respective source (S) terminals of the transistors 516a, 518a, e.g. the first terminal of the capacitor 514a is coupled to the source (S) terminal of the transistor 516a and the second terminal of the capacitor 514a is coupled to the source (S) terminal of the transistor 518a.

As shown in FIG. 5A, the drain (D) terminal of the transistor 516a is coupled to the first terminal of the inductor 502a, the first terminal of the capacitor 504a, the first terminal of the capacitor 510a and the gate (G) terminal of the transistor 522a. The drain (D) terminal of the transistor 516a and also the gate (G) terminal of the transistor 522a are also coupled to the first output terminal 506a. The drain (D) terminal of the transistor 518a is coupled to the second terminal of the inductor 502a, the second terminal of the capacitor 504a, the first terminal of the capacitor 512a and the gate (G) terminal of the transistor 520a. The drain (D) terminal of the transistor 518a and also the gate (G) terminal of the transistor 520a are also coupled to the second output terminal 508a.

As shown in FIG. 5A, the source (S) terminal of the transistor 516a is coupled to the second terminal of the capacitor 510a, the drain (D) terminal of the transistor 520a and the first terminal of the capacitor 514a. The source (S) terminal of the transistor 518a is coupled to the second terminal of the capacitor 512a, the drain (D) terminal of the transistor 522a and the second terminal of the capacitor 514a.

The first VCO 500a further includes an input terminal 524a, and a transistor (MP1) (e.g. fifth transistor) 526a and a transistor (MP2) (e.g. sixth transistor) 528a respectively having a source terminal, a drain terminal and a gate terminal. The source (S) terminal of the transistor 526a is coupled to the source (S) terminal of the transistor 528a, and the input terminal 524a is coupled between the source (S) terminal of the transistor 526a and the source (S) terminal of the transistor 528a.

The transistors 526a, 528a are PMOS, and form a cross-coupled pair of PMOS transistors. The gate terminal of the transistor 526a is coupled to the drain (D) terminal of the transistor 528a, the second terminal of the inductor 502a and the second output terminal 508a. The drain (D) terminal of the transistor 526a is coupled to the gate (G) terminal of the transistor 528a, the first terminal of the inductor 502a and the first output terminal 506a. As the Colpitts quadrature voltage controlled oscillator (“QVCO2”) of various embodiments does not require additional injection devices, and may favour a low supply voltage, incorporating the cross-coupled pair of PMOS transistors 526a, 528a may provide further gₘ enhancement through current re-using technique. However, it should be appreciated that the cross-coupled pair of PMOS transistors 526a, 528a may be optionally provided in the first VCO 500a.

The first VCO 500a further includes a capacitor (CS1) (e.g. fifth capacitor) 530a having a first terminal and a second terminal, a current source (e.g. first current source) 532a and a current source (e.g. second current source) 534a respectively having a first terminal (e.g. an input terminal) and a second terminal (e.g. an output terminal). The capacitor (CS1) 530a may be a source degeneration capacitor to reduce flicker noise. The first terminal of the capacitor 530a is coupled to the source (S) terminal of the transistor 520a and the first terminal of the current source 532a. The second terminal of the capacitor 530a is coupled to the source (S) terminal of the transistor 522a and the first terminal of the current source 534a. The second terminal of the current source 532a and the second terminal of the current source 534a are coupled to ground. Each of the current source 532a and the current source 534a are configured to supply a constant current to the first VCO 500a.

Each of the capacitor (CA1) 510a and the capacitor (CA2) 512a may have an at least substantially similar capacitance, C_{A}. In various embodiments, as the first VCO 500a is fully differential, the capacitor (CB1) 514a represents an equivalent capacitor of two capacitors (e.g. CB) in series. In other words, there are two capacitors in series between the source (S) terminal of the transistor (MC1) 516a and the source (S) terminal of the transistor (MC2) 518a. Each of the two capacitors (e.g. CB) in series may have an at least substantially similar capacitance, C_{B}, such that the equivalent capacitor (CB1) 514a has an equivalent capacitance of C_{B}/2. In addition, the capacitor (CS1) 530a has a capacitance, C_{S}.

As shown in FIG. 5B, the second VCO 500b includes an LC tank including an inductor (LT2) 502b and a capacitor (CT2) (e.g. first capacitor) 504b. The LC tank is configured to determine frequencies of the quadrature-phase output signals Q+ and Q−. Each of the inductor 502b and the capacitor 504b has a first terminal and a second terminal. The first terminal of the inductor 502b is coupled to the first terminal of the capacitor 504b and the second terminal of the inductor 502b is coupled to the second terminal of the capacitor 504b. The respective first terminals of the inductor 502b and the capacitor 504b are also coupled to a first output terminal 506b of the second VCO 500b, while the respective second terminals of the inductor 502b and the capacitor 504b are also coupled to a second output terminal 508b of the second VCO 500b. The capacitor 504b may be a variable capacitor.

The second VCO 500b further includes a capacitor (CA3) (e.g. second capacitor) 510b, a capacitor (CA4) (e.g. third capacitor) 512b and a capacitor (CB2) (e.g. fourth capacitor) 514b respectively having a first terminal and a second terminal. The capacitors 510b, 512b, 514b form a capacitive divider.

The second VCO 500b further includes a transistor (MC3) (e.g. first transistor) 516b, a transistor (MC4) (e.g. second transistor) 518b, a transistor (MN3) (e.g. third transistor) 520b and a transistor (MN4) (e.g. fourth transistor) 522b respectively having a source (S) terminal, a drain (D) terminal and a gate (G) terminal. The transistors 520b, 522b are NMOS, and form a current switching cross-coupled pair of NMOS transistors configured for current switching. The cross-coupled pair of transistors 520b, 522b are also configured to provide noise shaping and gₘ enhancement. The inductor 502b, the capacitors 504b, 510b, 512b, 514b, and the transistors 516b, 518b may form an oscillator core of the second VCO 500b.

As shown in FIG. 5B, the capacitor 510b is coupled across or between the source (S) terminal and the drain (D) terminal of the transistor 516b, e.g. the first terminal of the capacitor 510b is coupled to the drain (D) terminal of the transistor 516b and the second terminal of the capacitor 510b is coupled to the source (S) terminal of the transistor 516b.

The capacitor 512b is coupled across or between the source (S) terminal and the drain (D) terminal of the transistor 518b, e.g. the first terminal of the capacitor 512b is coupled to the drain (D) terminal of the transistor 518b and the second terminal of the capacitor 512b is coupled to the source (S) terminal of the transistor 518b.

The capacitor 514b is coupled between the capacitors 510b, 512b, and also coupled between the respective source (S) terminals of the transistors 516b, 518b, e.g. the first terminal of the capacitor 514b is coupled to the source (S) terminal of the transistor 516b and the second terminal of the capacitor 514b is coupled to the source (S) terminal of the transistor 518b.

As shown in FIG. 5B, the drain (D) terminal of the transistor 516b is coupled to the first terminal of the inductor 502b, the first terminal of the capacitor 504b, the first terminal of the capacitor 510b and the gate (G) terminal of the transistor 522b. The drain (D) terminal of the transistor 516b and also the gate (G) terminal of the transistor 522a are also coupled to the first output terminal 506b. The drain (D) terminal of the transistor 518b is coupled to the second terminal of the inductor 502b, the second terminal of the capacitor 504b, the first terminal of the capacitor 512b and the gate (G) terminal of the transistor 520b. The drain (D) terminal of the transistor 518b and also the gate (G) terminal of the transistor 520b are also coupled to the second output terminal 508b.

As shown in FIG. 5B, the source (S) terminal of the transistor 516b is coupled to the second terminal of the capacitor 510b, the drain (D) terminal of the transistor 520b and the first terminal of the capacitor 514b. The source (S) terminal of the transistor 518b is coupled to the second terminal of the capacitor 512b, the drain (D) terminal of the transistor 522b and the second terminal of the capacitor 514b.

The second VCO 500b further includes an input terminal 524b, and a transistor (MP3) (e.g. fifth transistor) 526b and a transistor (MP4) (e.g. sixth transistor) 528b respectively having a source terminal, a drain terminal and a gate terminal. The source (S) terminal of the transistor 526b is coupled to the source (S) terminal of the transistor 528b, and the input terminal 524b is coupled between the source (S) terminal of the transistor 526b and the source (S) terminal of the transistor 528b.

The transistors 526b, 528b are PMOS, and form a cross-coupled pair of PMOS transistors. The gate terminal of the transistor 526b is coupled to the drain (D) terminal of the transistor 528b, the second terminal of the inductor 502b and the second output terminal 508b. The drain (D) terminal of the transistor 526b is coupled to the gate (G) terminal of the transistor 528b, the first terminal of the inductor 502b and the first output terminal 506b. Similar to the cross-coupled pair of PMOS transistors 526a, 528a of the first VCO 500a, the cross-coupled pair of PMOS transistors 526b, 528b may be optionally provided in the second VCO 500b to provide further gₘ enhancement through current re-using technique.

The second VCO 500b further includes a capacitor (CS2) (e.g. fifth capacitor) 530b having a first terminal and a second terminal, a current source (e.g. first current source) 532b and a current source (e.g. second current source) 534b respectively having a first terminal (e.g. an input terminal) and a second terminal (e.g. an output terminal). The capacitor (CS2) 530b may be a source degeneration capacitor to reduce flicker noise. The first terminal of the capacitor 530b is coupled to the source (S) terminal of the transistor 520b and the first terminal of the current source 532b. The second terminal of the capacitor 530b is coupled to the source (S) terminal of the transistor 522b and the first terminal of the current source 534b. The second terminal of the current source 532b and the second terminal of the current source 534b are coupled to ground. Each of the current source 532b and the current source 534b are configured to supply a constant current to the second VCO 500b.

Each of the capacitor (CA3) 510b and the capacitor (CA4) 512b may have an at least substantially similar capacitance, C_{A}.

In various embodiments, as the second VCO 500b is fully differential, the capacitor (CB2) 514b represents an equivalent capacitor of two capacitors (e.g. CB) in series. In other words, there are two capacitors in series between the source (S) terminal of the transistor (MC3) 516b and the source (S) terminal of the transistor (MC4) 518b. Each of the two capacitors (e.g. CB) in series may have an at least substantially similar capacitance, C_{B}, such that the equivalent capacitor (CB2) 514b has an equivalent capacitance of C_{B}/2. In addition, the capacitor (CS2) 530b has a capacitance, C_{S}.

The first VCO 500a is an in-phase (I-phase) VCO, and the second VCO 500b is a quadrature-phase (Q-phase) VCO. The first output terminal 506a and the second output terminal 508a of the first VCO 500a respectively output a positive in-phase output signal (I+) and a negative in-phase output signal (I−). The first output terminal 506b and the second output terminal 508b of the second VCO 500b respectively output a positive quadrature-phase output signal (Q+) and a negative quadrature-phase output signal (Q−).

As shown in FIGS. 5A and 5B, the gate (G) terminal of the transistor 516a of the first VCO 500a is directly coupled to the first terminal of the inductor 502b of the second VCO 500b. The gate (G) terminal of the transistor 516a of the first VCO 500a is also directly coupled to the first output terminal (Q+) 506b of the second VCO 500b.

The gate (G) terminal of the transistor 518a of the first VCO 500a is directly coupled to the second terminal of the inductor 502b of the second VCO 500b. The gate (G) terminal of the transistor 518a of the first VCO 500a is also directly coupled to the second output terminal (Q−) 508b of the second VCO 500b.

The gate (G) terminal of the transistor 516b of the second VCO 500b is directly coupled to the second terminal of the inductor 502a of the first VCO 500a. The gate (G) terminal of the transistor 516b of the second VCO 500b is also directly coupled to the second output terminal (I−) 508a of the first VCO 500a.

The gate (G) terminal of the transistor 518b of the second VCO 500b is directly coupled to the first terminal of the inductor 502a of the first VCO 500a. The gate (G) terminal of the transistor 518b of the second VCO 500b is also directly coupled to the first output terminal (I+) 506a of the first VCO 500a.

Therefore, the I channel VCO signals inject into the Q channel oscillator core devices to cause anti-phase injection, and similarly the Q channel VCO signals inject into the I channel oscillator core devices, but with polarity swapping. For example, the gate (G) terminal of the transistor 516a of the first VCO 500a is biased with positive polarity, while the gate (G) terminal of the transistor 516b of the second VCO 500b is biased with negative polarity. Accordingly, the first VCO 500a and the second VCO 500b are interconnected or coupled with each other to constitute a feedback loop.

Each of the transistors 516a, 518a, 516b, 518b, may be an N-channel MOSFET (NMOS).

As shown in FIGS. 4A and 4B, and FIGS. 5A and 5B, the gate (G) terminals of the transistors (MC1) 416a or 516a, and (MC2) 418a or 518a in the I-phase VCO 400a or 500a are connected to the respective output terminals of the Q-phase VCO 400b or 500b, while the gate (G) terminals of the transistors (MC3) 416b or 516b, and (MC4) 418b or 518b in the Q-phase VCO 400b or 500b are connected to the respective output terminals of the I-phase VCO 400a or 500a in an inverse fashion.

Such a coupling topology or architecture does not require extra coupling devices, compared to conventional QVCOs that require coupling devices in parallel or in series with the oscillator core. For example, in conventional LC-QVCOs, quadrature signals are generated using anti-phase injection with additional injection devices in parallel or in series to couple two identical oscillators. The additional coupling devices or injection devices may dissipate additional power, increase phase noise, reduce the tuning range and cause a trade-off with I/Q phase accuracy and coupling efficiency, and may also induce active devices noise and degrade the VCO phase noise performance. Therefore, by providing direct coupling between the I-phase VCO and the Q-phase VCO, the QVCO of various embodiments may not suffer from the effects of the additional coupling devices as described above.

In various embodiments, for low-power consumption design considerations, the complementary cross-coupled pairs of transistors (MN1) 420a/520a and (MN2) 422a/522a, with cross-coupled pairs of transistors (MP1) 426a/526a and (MP2) 428a/528a of the first VCO 400a/500a, and/or the complementary cross-coupled pairs of transistors (MN3) 420b/520b and (MN4) 422b/522b, with cross-coupled pairs of transistors (MP3) 426b/526b and (MP4) 428b/528b of the second VCO 400b/500b, may be employed with the approach of current reuse, thereby further increasing the negative transconductance. In various embodiments, the tail current is split and coupled with the capacitor (CS1) 430a/530a or the capacitor (CS2) 430b/530b in order to reduce the flicker noise.

In various embodiments, each or some of the PMOS cross coupled pairs (e.g. 426a and 428a, 426b and 428b, 526a and 526b, 526b and 528b) may be included to further improve gₘ. Conventional series QVCO may suffer from limited headroom and may prohibit stacking of more devices. In contrast, the Colpitts quadrature voltage controlled oscillator (“QVCO1” and “QVCO2”) of various embodiments are suitable for low supply voltage, and these PMOS cross coupled pairs may be stacked to minimise the headroom requirement.

In various embodiments, the Colpitts quadrature voltage controlled oscillator (“QVCO2”) of the embodiment of FIGS. 5A and 5B requires a lower supply voltage compared to the Colpitts quadrature voltage controlled oscillator (“QVCO1”) of the embodiment of FIGS. 4A and 4B, as a result of the coupling topology or architecture of QVCO2.

Based on the design considerations described above, the quadrature VCOs of various embodiments feature very low phase noise with low power consumptions.

The results for the quadrature voltage controlled oscillators (QVCOs) of various embodiments will now be described, with respect to the Colpitts quadrature voltage controlled oscillator (“QVCO2”). However, it should be appreciated that substantially similar results may be obtained for the Colpitts quadrature voltage controlled oscillator (“QVCO1”).

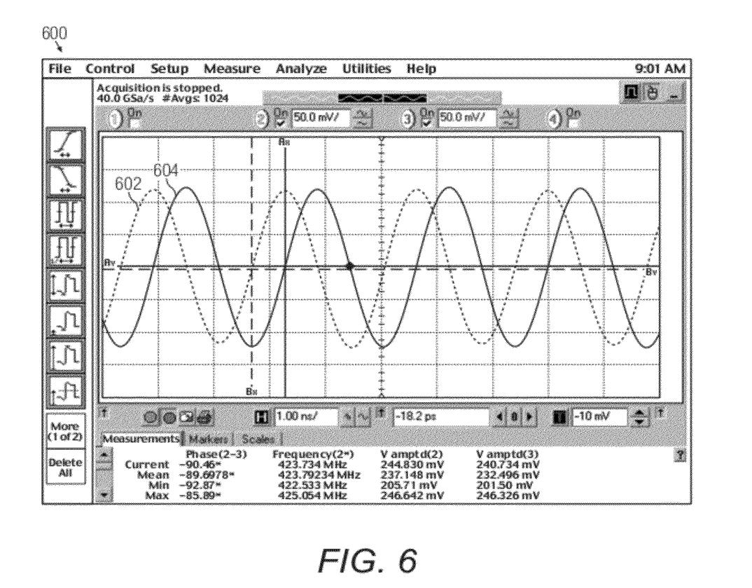

FIG. 6 shows a plot 600 of measured waveforms 602, 604, from the Colpitts quadrature voltage controlled oscillator (“QVCO2”) of various embodiments, for example as obtained using an oscilloscope. For example, the waveform 602 may be obtained from the I-phase VCO while the waveform 604 may be obtained from the Q-phase VCO of the Colpitts QVCO of various embodiments. As shown in FIG. 6, the waveforms 602, 604 show a quadrature phase relationship, i.e. a phase difference of 90°. The Colpitts QVCO of various embodiments show an average quadrature phase error of less than 0.3° (i.e. <0.3°).

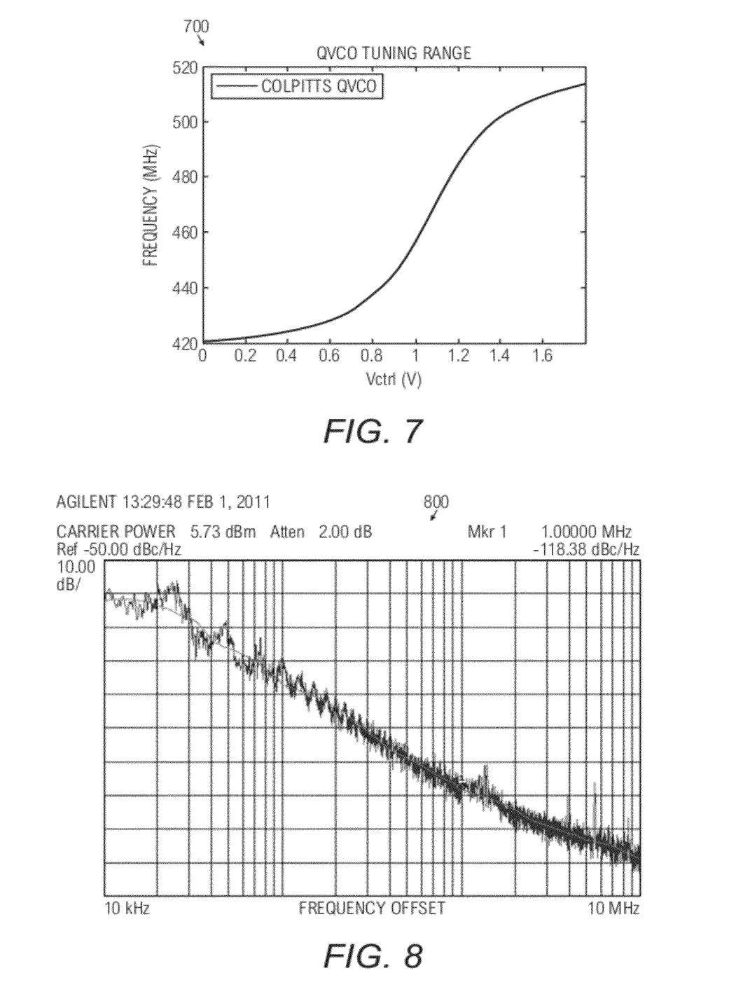

FIG. 7 shows a plot 700 of measured tuning range (TR) of the Colpitts quadrature voltage controlled oscillator (“QVCO2”) of various embodiments. The result shows a QVCO tuning range of about 20% of the center frequency of about 470 MHz.

FIG. 8 shows a plot 800 of measured phase noise of the Colpitts quadrature voltage controlled oscillator (“QVCO2”) of various embodiments. The result shows that the QVCO exhibits a phase noise of about −118 dBc/Hz at a frequency offset of about 1 MHz.

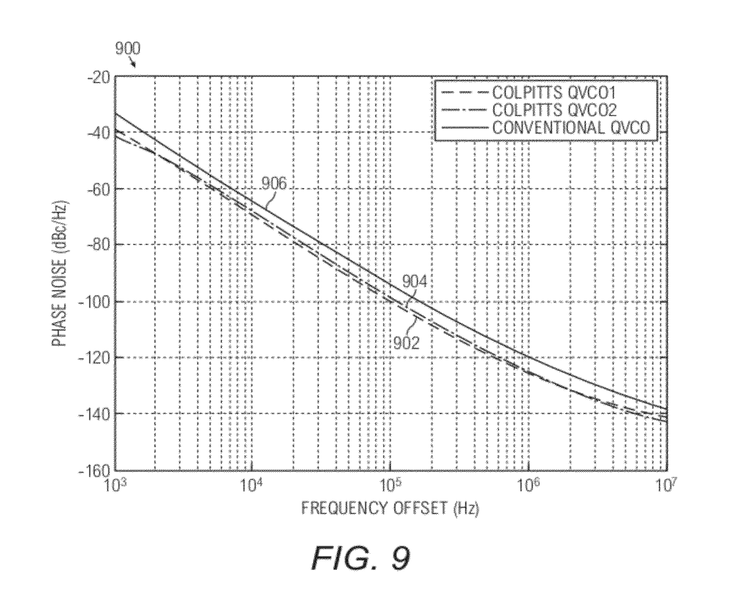

FIG. 9 shows a plot 900 of simulated phase noises of the Colpitts quadrature voltage controlled oscillators (QVCOs) of various embodiments and a conventional quadrature voltage controlled oscillator. The plot 900 shows the results 902 for the Colpitts QVCO (“QVCO1”) based on the first VCO 400a (FIG. 4A) and the second VCO 400b (FIG. 4B), the results 904 for the Colpitts QVCO (“QVCO2”) based on the first VCO 500a (FIG. 5A) and the second VCO 500b (FIG. 5B), and the results 906 for a conventional parallel-coupled QVCO (P-QVCO) in the frequency offset range from 1 kHz to 10 MHz. The results 902, 904 show that the difference in the phase noise of the Colpitts QVCO based on FIGS. 4A and 4B and the Colpitts QVCO based on FIGS. 5A and 5B is less than 1 dB from the interested close-in frequency offset to the far-out frequency offset. In addition, the Colpitts QVCOs of various embodiments out-perform the conventional P-QVCO by approximately 6 dB.

The VCO figure-of-merit (FOMT) may be calculated based on Equation 11:

$$FOMT = 10 log [ {( \frac{{ω}_{0}}{Δω} )}^{2} \cdot {( \frac{TR}{10 \%} )}^{2} \cdot \frac{1}{L ( Δω ) \cdot {P}_{diss / mW}} ] \qquad ( Equation 11 )$$

where ω₀ is the center frequency, TR is the tuning range, P_{diss} is the power dissipation in unit mW, and Δω and L(Δω) are the offset frequency with respect to the carrier and its single-sideband phase noise power spectral density.

Based on a drawn bias current of about 0.5 mA from a 1.8 V power supply, the FOMT values for QVCO1 and QVCO2 are about 180.3 dB and about 179.8 dB respectively, at about 1 MHz frequency offset.

The characteristics and the performances of the QVCO1 and the QVCO2 of various embodiments, obtained from simulation results, are shown in Table 1.

TABLE 1

| | QVCO1 | QVCO2 |
|---|---|---|
| Process | 0.18 μm CMOS | 0.18 μm CMOS |
| Operation | 475 | 475 |
| Frequency, F_{VCO} | | |
| (MHz) | | |
| Phase Noise @ | −125.5 | −125 |
| 1 MHz offset | | |
| (dBc/Hz) | | |
| Voltage (V) | 1.5 | 1.5 |
| Power (mW) | 0.75 | 0.75 |
| FOMT | 180.3 | 179.8 |

The characteristics and the performances of the QVCO2 of various embodiments, obtained from measurement results, are shown in Table 2.

TABLE 2

| | QVCO2 |
|---|---|
| Process | 0.18 μm CMOS |
| Operation Frequency, | 488 |
| F_{VCO} (MHz) | |
| Quality Factor of Inductor | 6.5 |
| Phase Noise @ 1 MHz offset | −118 |
| (dBc/Hz) | |
| Tuning Range (%) | 20 |
| I/Q Phase Error | 0.3° |
| Voltage (V) | 1.5 |
| Power (mW) | 0.75 |
| FOM | 173 |
| FOMT | 179 |

$where FOM = 10 log [ {( \frac{{ω}_{0}}{Δω} )}^{2} \cdot \frac{1}{L ( Δω ) \cdot {P}_{diss / mW}} ] and$ $FOMT = 10 log [ {( \frac{{ω}_{0}}{Δω} )}^{2} \cdot {( \frac{TR}{10 \%} )}^{2} \cdot \frac{1}{L ( Δω ) \cdot {P}_{diss / mW}} ] .$

While the preferred embodiments of the devices and methods have been described in reference to the environment in which they were developed, they are merely illustrative of the principles of the inventions. Other embodiments and configurations may be devised without departing from the spirit of the inventions and the scope of the appended claims.

We claim:

1. A quadrature voltage controlled oscillator, comprising:
a first voltage controlled oscillator and a second voltage controlled oscillator respectively comprising:
an inductor having a first terminal and a second terminal;
a first capacitor, a second capacitor, a third capacitor and a fourth capacitor respectively comprising a first terminal and a second terminal;
a first transistor, a second transistor, a third transistor and a fourth transistor respectively comprising a source terminal, a drain terminal and a gate terminal;
wherein the first terminal of the inductor is coupled to the first terminal of the first capacitor, and the second terminal of the inductor is coupled to the second terminal of the first capacitor;
wherein the drain terminal of the first transistor is coupled to the first terminal of the inductor, the first terminal of the first capacitor, the first terminal of the second capacitor, and the gate terminal of the fourth transistor;
wherein the drain terminal of the second transistor is coupled to the second terminal of the inductor, the second terminal of the first capacitor, the first terminal of the third capacitor, and the gate terminal of the third transistor;
wherein the source terminal of the first transistor is coupled to the second terminal of the second capacitor, the drain terminal of the third transistor, and the first terminal of the fourth capacitor;
wherein the source terminal of the second transistor is coupled to the second terminal of the third capacitor, the drain terminal of the fourth transistor, and the second terminal of the fourth capacitor;
wherein the gate terminal of the first transistor of the first voltage controlled oscillator is directly coupled to the first terminal of the inductor of the second voltage controlled oscillator;
wherein the gate terminal of the second transistor of the first voltage controlled oscillator is directly coupled to the second terminal of the inductor of the second voltage controlled oscillator;
wherein the gate terminal of the first transistor of the second voltage controlled oscillator is directly coupled to the second terminal of the inductor of the first voltage controlled oscillator;
wherein the gate terminal of the second transistor of the second voltage controlled oscillator is directly coupled to the first terminal of the inductor of the first voltage controlled oscillator.

2. The quadrature voltage controlled oscillator of claim 1, wherein the first voltage controlled oscillator further comprises:
a fifth transistor and a sixth transistor respectively comprising a source terminal, a drain terminal and a gate terminal;
an input terminal;
wherein the source terminal of the fifth transistor is coupled to the source terminal of the sixth transistor;
wherein the gate terminal of the fifth transistor is coupled to the drain terminal of the sixth transistor, the second terminal of the inductor and a second output terminal of the first voltage controlled oscillator;
wherein the drain terminal of the fifth transistor is coupled to the gate terminal of the sixth transistor, the first terminal of the inductor and a first output terminal of the first voltage controlled oscillator;
wherein the input terminal is coupled between the source terminal of the fifth transistor and the source terminal of the sixth transistor.

3. The quadrature voltage controlled oscillator of claim 1, wherein the first voltage controlled oscillator further comprises:
a fifth capacitor comprising a first terminal and a second terminal;
a first current source and a second current source respectively comprising a first terminal and a second terminal;
wherein the first terminal of the fifth capacitor is coupled to the source terminal of the third transistor and the first terminal of the first current source;
wherein the second terminal of the fifth capacitor is coupled to the source terminal of the fourth transistor and the first terminal of the second current source;
wherein the second terminal of the first current source and the second terminal of the second current source are coupled to ground.

4. The quadrature voltage controlled oscillator of claim 1, wherein the second voltage controlled oscillator further comprises:
a fifth transistor and a sixth transistor respectively comprising a source terminal, a drain terminal and a gate terminal;
an input terminal;
wherein the source terminal of the fifth transistor is coupled to the source terminal of the sixth transistor;
wherein the gate terminal of the fifth transistor is coupled to the drain terminal of the sixth transistor, the second terminal of the inductor and a second output terminal of the second voltage controlled oscillator;
wherein the drain terminal of the fifth transistor is coupled to the gate terminal of the sixth transistor, the first terminal of the inductor and a first output terminal of the second voltage controlled oscillator;
wherein the input terminal is coupled between the source terminal of the fifth transistor and the source terminal of the sixth transistor.

5. The quadrature voltage controlled oscillator of claim 1, wherein the second voltage controlled oscillator further comprises:
a fifth capacitor comprising a first terminal and a second terminal;
a first current source and a second current source respectively comprising a first terminal and a second terminal;
wherein the first terminal of the fifth capacitor is coupled to the source terminal of the third transistor and the first terminal of the first current source;
wherein the second terminal of the fifth capacitor is coupled to the source terminal of the fourth transistor and the first terminal of the second current source;
wherein the second terminal of the first current source and the second terminal of the second current source are coupled to ground.

6. The quadrature voltage controlled oscillator of claim 1, wherein the first voltage controlled oscillator is an in-phase voltage controlled oscillator, and the second voltage controlled oscillator is a quadrature-phase voltage controlled oscillator.

7. The quadrature voltage controlled oscillator of claim 1, wherein the first capacitor of the first voltage controlled oscillator and the first capacitor of the second voltage controlled oscillator comprise variable capacitors.
